(19) United States
(12) Patent Application Publication
(10) Pub. No.: US 2013/0068469 A1
(43) Pub. Date: Mar. 21, 2013

(54) Pressurized Polymer Beads As Proppants

(71) Applicants: Baojiu Lin, Houston, TX (US); Abdel Wadood M. El-Rabaa, Plano, TX (US); Richard S. Polizzotti, Milford, NJ (US)

(72) Inventors: Baojiu Lin, Houston, TX (US); Abdel Wadood M. El-Rabaa, Plano, TX (US); Richard S. Polizzotti, Milford, NJ (US)

(21) Appl. No.: 13/567,687

(22) Filed: Aug. 6, 2012

Related U.S. Application Data
(60) Provisional application No. 61/535,183, filed on Sep. 15, 2011.

(51) Int. Cl. C09K 8/80; C09K 8/62; C23C 16/06; E21B 43/00; B05D 7/00

(52) U.S. Cl. 166/369; 427/385.5; 427/250; 507/219; 507/201; 507/231; 507/225

(57) ABSTRACT

A pressurized polymer bead such as may be useful as a proppant in hydraulic fracturing is described, including a shell that is substantially impermeable, wherein the shell includes a polyimide polymer. The pressurized polymer bead includes a core region that is at a pressure that is greater than 5 MPa.

### RELATED APPLICATIONS

The present application claims the benefit of U.S. Provisional Application No. 61/535,183, filed Sep. 15, 2011, and is related to U.S. Pat. No. 8,088,716 (U.S. Patent Publication No. 2009/0090558) by Polizzotti, et al., entitled “Compressible Objects Having A Predetermined Internal Pressure Combined With A Drilling Fluid To Form A Variable Density Drilling Mud,” filed on Oct. 16, 2008, both of which are herein included by reference for all purposes.

### FIELD

The present techniques are directed to proppants for use in fracturing. More specifically, the proppants include pressurized polymer beads.

### BACKGROUND

This section is intended to introduce various aspects of the art, which may be associated with exemplary embodiments of the present techniques. This discussion is believed to assist in providing a framework to facilitate a better understanding of particular aspects of the present techniques. Accordingly, it should be understood that this section should be read in this light, and not necessarily as admissions of prior art.

After hydrocarbons that are easily harvested from reservoirs are extracted by primary oil recovery, e.g., under the natural pressure in a reservoir, other techniques may be used to increase the amounts of hydrocarbons that may be harvested. For example, secondary oil recovery may be used to recover a larger amount of hydrocarbon. In secondary oil recovery, fluids are pumped into a first well or wells and hydrocarbons are recovered from fluids harvested from a second well or wells. The injected fluids may include water or carbon dioxide, or any combinations thereof. The harvested fluids may include hydrocarbons, the injected fluids, and other natural fluids in the reservoir, such as brine.

Once secondary oil recovery becomes uneconomical, additional techniques, generally termed enhanced oil recovery (EOR) or tertiary oil recovery can be implemented on a reservoir to increase production. For example, steam flooding to increase the temperature of the reservoir, the injection of surfactants, or other techniques to stimulate reservoirs may be used, such as hydraulic fracturing.

Hydraulic fracturing has been used in stimulating reservoir productivity for decades. During hydraulic fracturing, high pressure fracturing fluid is injected into a well to create fractures in reservoirs to increase reservoir permeability and reservoir contacts. Most extensive use of hydraulic fracturing is in what is known as unconventional reservoirs such as tight sandstone, shale gas, coal bed methane, tight oil reservoirs, and tight limestones. As used herein, “tight” is a description of very low permeability reservoirs which do not produce economically without hydraulic fracturing. These reservoirs often hold natural gas reserves that cannot be accessed due to the low permeability of the rock.

The fractures are often held open by the use of proppants, which are particles placed inside the fractures to keep them open when the injection pressure is released. The size, shape, strength, and density of the proppants have significant effects on operation and cost in hydraulic fracturing. There are two useful properties for proppants. The first is a high strength for deeper reservoir use. The second is a specific gravity less than the hydraulic fracturing fluids.

Proppants are not limited to enhanced oil recovery, but have recently been used in primary recovery of hydrocarbons from unconventional reservoirs. One such unconventional hydrocarbon source is natural gas produced from rocks that form unconventional gas reservoirs, including, for example, shale and coal seams. A significant increase in shale gas production has resulted from hydraulic fracturing of these unconventional gas reservoirs. When combined with horizontal drilling, which is often used with wells in tight gas reservoirs, the hydraulic fracturing and propping may allow formerly unpractical reservoirs to be commercially viable.

Currently, commercial proppants can include natural proppants, such as sands, resin coated natural sands, shell fragments, and the like. Artificial materials may also be used as proppants, including sintered bauxite and ceramics, resin coated ceramics, lite weight proppants, ultra weight proppants, and the like. However, commercial proppants are often heavier than water and may sink to the bottom of fractures during injection, lowering the efficiency of the propping process. Further, current commercial available lite/ultra weight proppants, which may be more closely matched to the density of water, are not strong enough to prop open high pressure fractures (>6,000 psi).

A commonly used fluid in fracturing is termed “slick water.” Slick water is mostly water with a small amount, around 1%, of friction reducer and other additives. The friction reducing additives allow for a faster pumping rate into a formation, leading to an increase in the number and size of the fractures formed. However, slick water does not efficiently carry higher density proppants, such as sands. When proppants are dropped due to gravity settling, slick water fractures are often not effective to cover thick reservoirs. This can cause reserves to be left behind.

Various solutions have been proposed to create lower density proppants that may not settle as quickly. For example, U.S. Patent Publication No. 2010/0285998, Estur, et al., discloses “polyamide beads and method for the production thereof.” The polyamide beads are asserted to be useful as a sustaining material for underground natural or artificial cracks of the earth's crust. The cracks are essentially employed for the extraction of hydrocarbons such as crude oil or natural gas. The polyamide beads have a spherical or ellipsoidal shape and have a surface free of concave portions, advantageously have a uniform shape, a mean diameter lower than or equal to 1.7 mm, and a porosity lower than 0.1 ml/g. The polyamide beads are produced using a particular cutting device/extruder.

Further, U.S. Pat. No. 7,036,591 to Cannan, et al., discloses a “low density proppant.” The low density, spherical proppant is made from kaolin clay having an alumina content distributed homogeneously throughout the pellets. The apparent specific gravity of the proppant is from 1.60 to 2.10 g/cc, and a bulk density of from 0.95 to 1.30 g/cc. The low density is achieved by controlling the time and temperature of the firing process to be from 1200 to 1350° C. This low density proppant is useful in hydraulic fracturing of shallow oil and gas wells.

However, solid polymer beads have a density that is determined by the material properties. Accordingly, adjustment of the density is limited by the material selections. Further, the ceramic beads are limited in strength to shallower wells, e.g., less than 1667 meters (5000 ft).

Proppants that can be adjusted for a wide range of reservoir applications may lead to more productive reservoirs. In other words, a greater amount of the gas, or other hydrocarbon, trapped in a relatively non-porous reservoir, such as a tight gas, shale layer or coal seam may be harvested. Accordingly, numerous researchers have explored ways to improve proppants.

### SUMMARY

An embodiment provides a pressurized polymer bead for use as a proppant in hydraulic fracturing. The pressurized polymer bead includes a shell that is substantially impermeable, wherein the shell includes a polyimide polymer. The pressurized polymer bead includes a core region that is at a pressure that is greater than or equal to (not less than) 5 MPa.

Another embodiment provides a fracturing fluid that includes a carrier fluid and a plurality of pressurized beads mixed with the carrier fluid. The pressurized beads include a substantially impermeable outer shell formed from a polyimide polymer and a core region that is at a pressure that is greater than or equal to 5 MPa

Another embodiment provides a method for manufacturing a pressurized polymer bead. The method includes forming a bubble including a monomer solution, wherein the monomer solution includes a polyamic acid and dropping the bubble into a heated gas tube to form a dry hollow bead. The hollow bead is dropped into a chemical bath to form a partially imidized bead and the partially imidized bead is heated in the presence of a pressurized gas to form the pressurized bead

Yet another embodiment provides a method for harvesting hydrocarbons from a reservoir. The method includes injecting a fracturing fluid into a reservoir to create fractures in rock in the reservoir. The fracturing fluid includes a carrier fluid and pressurized beads mixed with the carrier fluid. The pressurized beads include a substantially impermeable outer shell formed from a polyimide polymer and a core region that is at a pressure that is not less than 5 MPa. The carrier fluid is withdrawn from the reservoir, leaving at least a portion of the pressurized beads in the fractures. A hydrocarbon is produced from the reservoir through the fractures.

### DESCRIPTION OF THE DRAWINGS

The advantages of the present techniques are better understood by referring to the following detailed description and the attached drawings, in which:

FIG. 1 is a diagram of a hydraulic fracturing process;

FIG. 2 is an expanded view of a fracture from a well, showing the placement of proppant particles within the fracture;

FIG. 3 is a chart comparing the strengths of various materials that may be used as proppant;

FIG. 4 is a drawing of a pressurized polymer bead;

FIG. 5 is a schematic of a synthesis system that may be used to form pressurized polymer beads;

FIG. 6 is an electron micrograph of a pressurized polymer bead with a hollow core, which has been sectioned to show the wall dimensions;

FIG. 7 is an electron micrograph of a pressurized polymer bead with a foamed core, which has been sectioned to show the dimensions;

FIG. 8 are plots of a simulation of travel distance in a propped fracture for a conventional Brady sand in comparison to the low density, pressurized polymer beads;

FIG. 9 is a plot of cumulative production from a reservoir;

FIG. 10 is a drawing of a pressurized polymer bead compressed between two parallel rigid platens;

FIG. 11 is a plot of a tension test on a piece of polyimide film of the same composition as the pressurized polymer beads;

FIG. 12 is a drawing of a stress distribution on a pressurized polymer bead calculated by finite element analysis (FEA) for a pressurized polymer bead under the loading condition of FIG. 10;

FIG. 13 is a plot of the load capacities of a pressurized polymer bead;

FIG. 14 is a drawing of a stress distribution on a pressurized polymer bead calculated by finite element analysis (FEA) for 100 MPa (14,504 psi) external pressure with no internal pressure;

FIG. 15 is a drawing of a stress distribution on a pressurized polymer bead calculated by finite element analysis (FEA) when the pressurized polymer bead experiences free expansion under 15000 psi internal gas pressure;

FIG. 16 is a drawing of a pressurized polymer bead having a protective coating as an outside layer over a hollow shell enclosing a pressurized cavity;

FIG. 17 is a drawing of a similar pressurized polymer bead having a protective layer over a shell that holds a pressurized foamed core;

FIG. 18 is a drawing of a pressurized polymer bead having a sealing layer over a hollow shell that encloses a pressurized cavity;

FIG. 19 is a drawing of a pressurized polymer bead having a sealing layer formed along the inside surface of a hollow shell;

FIG. 20 is a drawing of a pressurized polymer bead having a sealing layer over a shell that holds a pressurized foamed core;

FIG. 21 is a drawing of a pressurized polymer bead having a sealing layer over a hollow shell enclosing a pressurized cavity with a protective coating 1602 as an outside layer over the sealing layer;

FIG. 22 is a drawing of a pressurized polymer bead having a sealing layer formed along the inner surface of a hollow shell, with a protective coating as an outside layer over the hollow shell; and

FIG. 23 is a drawing of a pressurized polymer bead having a sealing layer applied over a shell that includes a pressurized foamed core, with a protective coating applied over the sealing layer.

### DETAILED DESCRIPTION

In the following detailed description section, specific embodiments of the present techniques are described. However, to the extent that the following description is specific to a particular embodiment or a particular use of the present techniques, this is intended to be for exemplary purposes only and simply provides a description of the exemplary embodiments. Accordingly, the techniques are not limited to the specific embodiments described below, but rather, include all alternatives, modifications, and equivalents falling within the true spirit and scope of the appended claims.

At the outset, for ease of reference, certain terms used in this application and their meanings as used in this context are set forth. To the extent a term used herein is not defined below, it should be given the broadest definition persons in the pertinent art have given that term as reflected in at least one printed publication or issued patent. Further, the present techniques are not limited by the usage of the terms shown below, as all equivalents, synonyms, new developments, and terms or techniques that serve the same or a similar purpose are considered to be within the scope of the present claims.

“Exemplary” is used exclusively herein to mean “serving as an example, instance, or illustration.” Any embodiment described herein as exemplary is not to be construed as preferred or advantageous over other embodiments.

A “facility” is tangible piece of physical equipment, or group of equipment units, through which hydrocarbon fluids are either produced from a reservoir or injected into a reservoir. In its broadest sense, the term facility is applied to any equipment that may be present along the flow path between a reservoir and its delivery outlets, which are the locations at which hydrocarbon fluids either leave the model (produced fluids) or enter the model (injected fluids). Facilities may comprise production wells, injection wells, well tubulars, wellhead equipment, gathering lines, manifolds, pumps, compressors, separators, surface flow lines, and delivery outlets. In some instances, the term “surface facility” is used to distinguish those facilities other than wells.

“Formation” refers to a body of rock or other subsurface solids that is sufficiently distinctive and continuous that it can be mapped, for example, by seismic techniques. A formation can be a body of rock of predominantly one type or a combination of types. A formation can contain one or more hydrocarbon-bearing zones. Note that the terms formation, hydrocarbon reservoir, and interval may be used interchangeably, but will generally be used to denote progressively smaller subsurface regions, zones, or volumes. More specifically, a formation will generally be the largest subsurface region, a hydrocarbon reservoir will generally be a region within the formation and will generally be a hydrocarbon-bearing zone (a formation, reservoir, or interval having oil, gas, heavy oil, and any combination thereof), and an interval will generally refer to a sub-region or portion of a reservoir. A hydrocarbon-bearing zone can be separated from other hydrocarbon-bearing zones by zones of lower permeability such as mudstones, shales, or shale-like (highly compacted) sands. In one or more embodiments, a hydrocarbon-bearing zone includes heavy oil in addition to sand, clay, or other porous solids.

A “fracture” is a crack or surface of breakage within rock not related to foliation or cleavage in metamorphic rock along which there has been minimal movement. A fracture along which there has been lateral displacement may be termed a fault. When walls of a fracture have moved only normal to each other, the fracture may be termed a joint. Fractures may enhance permeability of rocks greatly by connecting pores together, and for that reason, joints and faults may be induced mechanically in some reservoirs in order to increase fluid flow.

“Fracturing” refers to the structural degradation of a treatment interval, such as a subsurface shale formation, from applied thermal or mechanical stress. Such structural degradation generally enhances the permeability of the treatment interval to fluids and increases the accessibility of the hydrocarbon component to such fluids. Fracturing may also be performed by degrading rocks in treatment intervals by chemical means.

“Fracture gradient” refers to an equivalent fluid pressure sufficient to create or enhance one or more fractures in the subterranean formation. As used herein, the “fracture gradient” of a layered formation also encompasses a parting fluid pressure sufficient to separate one or more adjacent bedding planes in a layered formation. It should be understood that a person of ordinary skill in the art could perform a simple leak-off test on a core sample of a formation to determine the fracture gradient of a particular formation.

“Hydraulic fracturing” is used to create single or branching fractures that extend from the wellbore into reservoir formations so as to stimulate the potential for production. A fracturing fluid, which may be a viscous fluid or a slick water fluid, is injected into the formation with sufficient pressure to create and extend a fracture, and a proppant is used to “prop” or hold open the created fracture after the hydraulic pressure used to generate the fracture has been released. When pumping of the treatment fluid is finished, the fracture “closes.” Loss of fluid to permeable rock results in a reduction in fracture width until the proppant supports the fracture faces. The fracture may be artificially held open by injection of a proppant material. Hydraulic fractures may be substantially horizontal in orientation, substantially vertical in orientation, or oriented along any other plane. Generally, the fractures tend to be vertical at greater depths, due to the increased mass of the overburden. As used herein, fracturing may take place in portions of a formation outside of a hydrocarbon reservoir in order to enhance hydrocarbon production from the hydrocarbon reservoir.

“Hydraulic fracture conductivity” is the product of the created hydraulic fracture width times the permeability of proppant inside the fracture at downhole conditions of temperature, pressure, and applied in-situ stress. The main objective of the proppant selected is to create the highest fracture conductivity as possible and the even distribution of the proppant over all of the fractured area.

“Hydrocarbon production” refers to any activity associated with extracting hydrocarbons from a well or other opening. Hydrocarbon production normally refers to any activity conducted in or on the well after the well is completed. Accordingly, hydrocarbon production or extraction includes not only primary hydrocarbon extraction but also secondary and tertiary production techniques, such as injection of gas or liquid for increasing drive pressure, mobilizing the hydrocarbon or treating by, for example chemicals or hydraulic fracturing the wellbore to promote increased flow, well servicing, well logging, and other well and wellbore treatments.

“Hydrocarbons” are generally defined as molecules formed primarily of carbon and hydrogen atoms such as oil and natural gas. Hydrocarbons may also include other elements, such as, but not limited to, halogens, metallic elements, nitrogen, oxygen, and/or sulfur. Hydrocarbons may be produced from hydrocarbon reservoirs through wells penetrating a hydrocarbon containing formation. Hydrocarbons derived from a hydrocarbon reservoir may include, but are not limited to, kerogen, bitumen, pyrobitumen, asphaltenes, oils, natural gas, or combinations thereof. Hydrocarbons may be located within or adjacent to mineral matrices within the earth. Matrices may include, but are not limited to, sedimentary rock, sands, silicilytes, carbonates, diatomites, and other porous media.

A “hydraulic fracture” is a fracture at least partially propagated into a formation, wherein the fracture is created through injection of pressurized fluids into the formation. While the term “hydraulic fracture” is used, the techniques described herein are not limited to use in hydraulic fractures. The techniques may be suitable for use in any fractures created in any manner considered suitable by one skilled in the art. Hydraulic fractures may be substantially horizontal in orientation, substantially vertical in orientation, or oriented along any other plane. Generally, the fractures tend to be vertical at greater depths, due to the increased mass of the overburden.

“Imbibition” refers to the incorporation of a fracturing fluid into a fracture face by capillary action. Imbibition may result in decreases in permeation of a formation fluid across the fracture face, and is known to be a form of formation damage. For example, if the fracturing fluid is an aqueous fluid, imbibition may result in lower transport of organic materials, such as hydrocarbons, across the fracture face, resulting in decreased recovery. The decrease in hydrocarbon transport may outweigh any increases in fracture surface area resulting in no net increase in recovery, or even a decrease in recovery, after fracturing.

As used herein, “material properties” represents any number of physical constants that influence fracture mechanics. Such material properties may include, for example, Young's modulus (E), Poisson's Ratio (ν), tensile strength, compressive strength, shear strength, creep behavior, and other properties. The material properties may be measured by any combinations of tests, including, among others, a “Standard Test Method for Unconfined Compressive Strength of Intact Rock Core Specimens,” ASTM D 2938-95; a “Standard Test Method for Splitting Tensile Strength of Intact Rock Core Specimens [Brazilian Method],” ASTM D 3967-95a Reapproved 1992; a “Standard Test Method for Determination of the Point Load Strength Index of Rock,” ASTM D 5731-95; “Standard Practices for Preparing Rock Core Specimens and Determining Dimensional and Shape Tolerances,” ASTM D 4435-01; “Standard Test Method for Elastic Moduli of Intact Rock Core Specimens in Uniaxial Compression,” ASTM D 3148-02; “Standard Test Method for Triaxial Compressive Strength of Undrained Rock Core Specimens Without Pore Pressure Measurements,” ASTM D 2664-04; “Standard Test Method for Creep of Cylindrical Soft Rock Specimens in Uniaxial Compressions,” ASTM D 4405-84, Reapproved 1989; “Standard Test Method for Performing Laboratory Direct Shear Strength Tests of Rock Specimens Under Constant Normal Stress,” ASTM D 5607-95; “Method of Test for Direct Shear Strength of Rock Core Specimen,” U.S. Military Rock Testing Handbook, RTH-203-80, available at “http://www.wes.army.mil/SUMTC/handbook/RT/RTH/203-80.pdf” (last accessed on Jun. 25, 2010); and “Standard Method of Test for Multistage Triaxial Strength of Undrained Rock Core Specimens Without Pore Pressure Measurements,” U.S. Military Rock Testing Handbook, available at http://www.wes.army.mil/SL/MTC/handbook/RT/RTH/204-80.pdf” (last accessed on Jun. 25, 2010). One of ordinary skill will recognize that other methods of testing rock specimens may be used to determine the physical constants used herein.

“Natural gas” refers to various compositions of raw or treated hydrocarbon gases. Raw natural gas is primarily comprised of light hydrocarbons such as methane, ethane, propane, butanes, pentanes, hexanes and impurities like benzene, but may also contain small amounts of non-hydrocarbon impurities, such as nitrogen, hydrogen sulfide, carbon dioxide, and traces of helium, carbonyl sulfide, various mercaptans, or water. Treated natural gas is primarily comprised of methane and ethane, but may also contain small percentages of heavier hydrocarbons, such as propane, butanes, and pentanes, as well as small percentages of nitrogen and carbon dioxide.

“Overburden” refers to the subsurface formation overlying the formation containing one or more hydrocarbon-bearing zones (the reservoirs). For example, overburden may include rock, shale, mudstone, or wet/tight carbonate (such as an impermeable carbonate without hydrocarbons). An overburden may include a hydrocarbon-containing layer that is relatively impermeable. In some cases, the overburden may be permeable.

“Overburden stress” refers to the load per unit area or stress overlying an area or point of interest in the subsurface from the weight of the overlying sediments and fluids. In one or more embodiments, the “overburden stress” is the load per unit area or stress overlying the hydrocarbon-bearing zone that is being conditioned or produced according to the embodiments described. In general, the magnitude of the overburden stress will primarily depend on two factors: 1) the composition of the overlying sediments and fluids, and 2) the depth of the subsurface area or formation. Similarly, underburden refers to the subsurface formation underneath the formation containing one or more hydrocarbon-bearing zones (reservoirs).

“Permeability” is the capacity of a rock to transmit fluids through the interconnected pore spaces of the rock. Permeability may be measured using Darcy's Law: Q=(k ΔP A)/(μL), where Q=flow rate (cm³/s), ΔP=pressure drop (atm) across a cylinder having a length L (cm) and a cross-sectional area A (cm²), μ=fluid viscosity (cp), and k=permeability (Darcy). The customary unit of measurement for permeability is the millidarcy. The term “relatively permeable” is defined, with respect to formations or portions thereof, as an average permeability of 10 millidarcy or more (for example, 10 or 100 millidarcy). The term “relatively low permeability” is defined, with respect to formations or portions thereof, as an average permeability of less than 10 millidarcy. An impermeable layer generally has a permeability of less than 0.1 millidarcy. By these definitions, shale may be considered impermeable, for example, ranging from 0.1 millidarcy (100 microdarcy) to as low as 0.00001 millidarcy (10 nanodarcy).

“Porosity” is defined as the ratio of the volume of pore space to the total bulk volume of the material expressed in percent. Although there often is an apparent close relationship between porosity and permeability, because a highly porous rock may be highly permeable, there is no real relationship between the two; a rock with a high percentage of porosity may be very impermeable because of a lack of communication between the individual pores, capillary size of the pore space or the morphology of structures constituting the pore space. For example, the diatomite in one exemplary rock type, Belridge, has very high porosity, at 60%, but the permeability is very low, for example, less than 0.1 millidarcy.

“Pressure” refers to a force acting on a unit area. Pressure is usually shown as pounds per square inch (psi). “Atmospheric pressure” refers to the local pressure of the air. Local atmospheric pressure is assumed to be 14.7 psia, the standard atmospheric pressure at sea level. “Absolute pressure” (psia) refers to the sum of the atmospheric pressure plus the gauge pressure (psig). “Gauge pressure” (psig) refers to the pressure measured by a gauge, which indicates only the pressure exceeding the local atmospheric pressure (a gauge pressure of 0 psig corresponds to an absolute pressure of 14.7 psia).

“Proppants” are particles placed inside fractures formed in a reservoir rock to hold the fractures open when the injection pressure is released. The fractures can be formed by hydraulic fracturing, thermal fracturing, or any number of other techniques. The proppants can include sand, ceramic spheres, plastic spheres, and the like. The proppants are mixed into a fluid and pumped into the reservoir while the fractures are held open, usually by pressure applied using the fracturing fluid.

As previously mentioned, a “reservoir” or “hydrocarbon reservoir” is defined as a pay zone (for example, hydrocarbon-producing zones) that includes sandstone, limestone, chalk, coal, and some types of shale. Pay zones can vary in thickness from less than one foot (0.3048 m) to hundreds of feet (hundreds of m). The permeability of the reservoir formation provides the potential for production.

“Shale” is a fine-grained clastic sedimentary rock with a mean grain size of less than 0.0625 mm. Shale typically includes laminated and fissile siltstones and claystones. These materials may be formed from clays, quartz, and other minerals that are found in fine-grained rocks. Non-limiting examples of shales include Barnett, Fayetteville, and Woodford in North America. Shale has low matrix permeability, so gas production in commercial quantities requires fractures to provide permeability. Shale gas reservoirs may be hydraulically fractured to create extensive artificial fracture networks around wellbores. Horizontal drilling is often used with shale gas wells.

“Strain” is the fractional change in dimension or volume of the deformation induced in a material by applying stress. For most materials, strain is directly proportional to the stress, and depends upon the flexibility of the material. This relationship between strain ε and stress σ is known as Hooke's law, and is presented by the formula: ρ=Eε.

“Stress” is the application of force to a material, such as a through a hydraulic fluid used to fracture a formation. Stress can be measured as force per unit area. Thus, applying a longitudinal force f to a cross-sectional area S of a strength member yields a stress which is given by f/S.

“Substantial” when used in reference to a quantity or amount of a material, or a specific characteristic thereof, refers to an amount that is sufficient to provide an effect that the material or characteristic was intended to provide. The exact degree of deviation allowable may in some cases depend on the specific context.

### Overview

Exemplary embodiments of the present techniques provide proppants for holding open fractures in rock. The fractures are formed during fracture stimulation of reservoirs using a high-pressure fluid pumped into the reservoir and the proppants are introduced to the formation as a mixture in the fracturing fluid. The proppants include pressurized polymer beads. The core of the pressurized polymer beads may be hollow or may include a foamed material, in addition to a pressurized gas. The pressurized polymer beads utilize the pressurized gas to redistribute stress across the beads, propping open the fractures and increasing the efficiency of material usage. By adjusting the internal pressure and wall thickness of these pressurized polymer beads, the load capacity of the material can be maximized for use as proppants.

Further, adjusting the wall thickness may be used to substantially match the density of the pressurized polymer beads with a carrier fluid. This allows the beads to travel much farther into a fracture before settling than sand or other high density proppants. The substantially matching density may allow for the pressurized polymer beads to be used more efficiently in fracturing fluids that use flow enhancing additives, e.g., slick water fracturing fluids. As slick water fracturing fluids allow faster pumping of the fracturing fluids into the subsurface, higher pressures can be achieved in the reservoir, creating longer fractures. The improved suspension of the pressurized polymer beads in the slick water fracturing fluids may provide substantial improvements over other fracturing fluid/proppant combinations. In embodiments, the techniques and materials can be used to enhance production of natural gas from unconventional, i.e., low permeability, gas reservoirs.

The pressurized polymer beads can be used with other, heavier, proppants to provide full coverage of the fracture and reduce the total amount of proppants used for fracturing. In some embodiments, the pressurized polymer beads are round particles that have a diameter of 0.5 mm to 1.0 mm, the strength to withstand closure stresses of 5000 psi to 10,000 psi, and a density not greater than 0.95 g/cc. In some embodiments, the pressurized polymer beads have a density not greater than 1.1 g/cc.

In addition to gas pressurization, some of the polymer beads can be intentionally pressurized with liquids. These beads can be designed so that, if they broke, the liquid will be released and improve fracture conductivity. These contents may include materials such as acids, oxidizers, or enzymes that can help to clean-up or chemically remove damage or contamination between the proppant particles that may impede fracture conductivity. For example, the residues may include residues of fracturing fluid polymers, such as guars or any other components of the fracturing fluids. Other damage that may impede fluid flow in the fracture can include fines that were generated from abrasive action on the fracture face, proppant embedment in the fracture face, or any other damaging residues left from the fracture fluids or from the formation, such as salts or residues of other chemical additives used in the fracturing fluids. The pressurized fluids can be acids, oxidizers, and enzymes, among others.

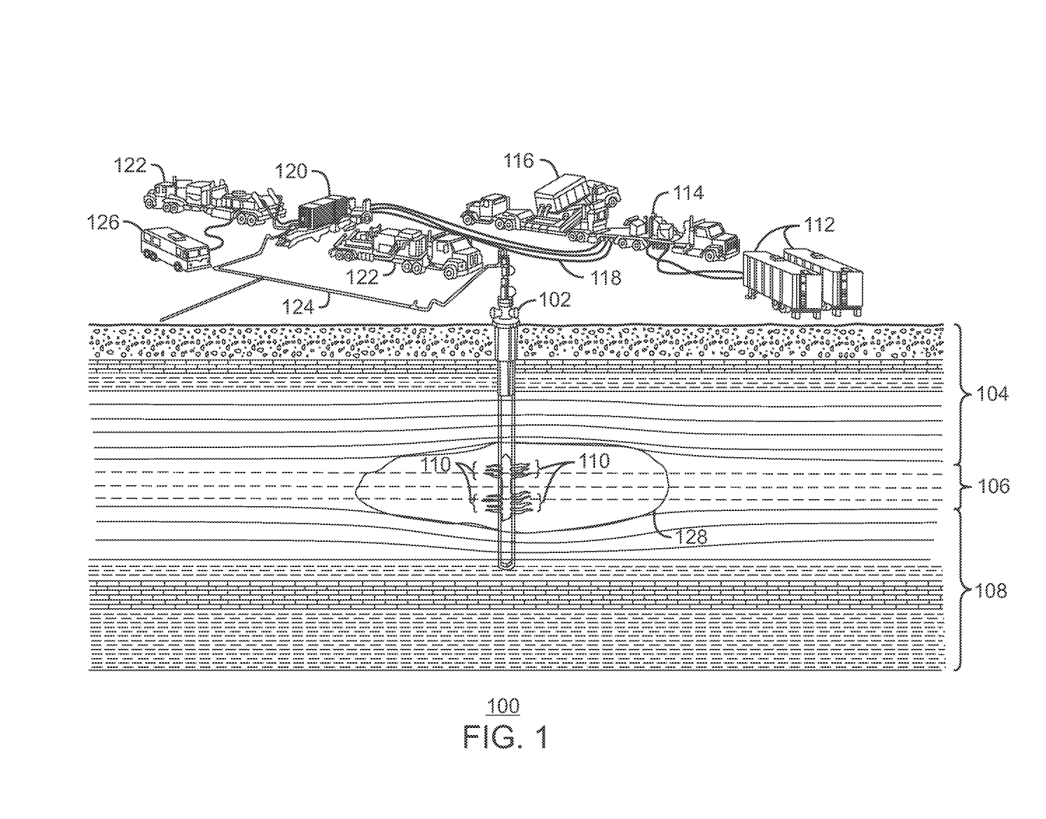

FIG. 1 is a simplified diagram of a hydraulic fracturing process 100. The traditional method of fracture stimulation utilizes “hydraulic” pressure pumping and is a proven technology that has been used, since the 1940s, in more than 1 million wells in the United States to help produce oil and natural gas. In typical oilfield operations, the technology involves pumping a water-proppant mixture into subterranean rock layers where the oil or gas is trapped. The pressure of the water creates tiny fissures or fractures in the rock. After pumping is finished the proppant holds open the fractures, allowing the oil or gas to escape from the rock and flow up a well.

For example, a well 102 may be drilled through an overburden 104 to a hydrocarbon reservoir 106. Although the well 102 may penetrate through the hydrocarbon reservoir 106 and into the underburden 108, perforations 110 in the well 102 can direct fluids to and from the hydrocarbon reservoir 106. The hydraulic fracturing process 100 may utilize an extensive amount of equipment at the well site. This equipment may include fluid storage tanks 112 to hold the fracturing fluid, and blenders 114 to blend the fracturing fluid with other materials, such as proppant 116 and other chemical additives, forming a low pressure slurry. The low pressure slurry 118 may be run through a treater manifold 120, which may use pumps 122 to adjust flow rates, pressures, and the like, creating a high pressure slurry 124, which can be pumped down the well 102 to fracture the rocks in the hydrocarbon reservoir 106. A mobile command center 126 may be used to control the fracturing process. It can be noted that the arrangement described above is merely exemplary. Any combinations of arrangements and equipment may be used with the pressurized polymer beads described herein.

The goal of hydraulic fracture stimulation is to create a highly-conductive fracture zone 128 by engineering subsurface stress conditions to induce pressure parting of the rock in the hydrocarbon reservoir 106. This may be improved by injecting fracturing fluids with a proppant 116 having a high permeability, or flow rate, such as the pressurized polymer beads discussed herein. As used herein, a high permeability proppant 116 may flow a longer distance into a fracture before settling or being trapped.

The fracturing fluid may include additives to form slick water, which may increase the flow rate of the fracturing fluid into the reservoir. Such slick water additives may include, among others, a polymer, a long chain hydrocarbon, an ionic surfactant, a nonionic surfactant, a polyacrylamide, a polyethylene oxide (PEO), or any combinations thereof. The fracturing fluid may also include any number of other additives in addition to or instead of the slick water additives. Such additives may include, for example, polymer gelling agents, acids, bases, biocides, corrosion inhibitors, and the like.

The fracture zone 128 may be considered a network or “cloud” of fractures generally radiating out from the well 102. Depending on the depth of the hydrocarbon reservoir 106, the fractures may often be perpendicular to the bedding planes, e.g., vertical within the subsurface.

After the fracturing process 100 is completed, the treating fluids are flowed back to minimize formation damage. For example, leaving the reservoir rock in contact with the fracturing fluids may result in imbibement of the fluids by pores in the hydrocarbon reservoir 106, which may actually lower the productivity of the reservoir. Further, a carefully controlled flowback may ensure proper fracture closure, trapping the proppant 116 in the fractures to hold them open. Stimulation is generally effective at near-well scale, for example, in which the fracture dimensions are in the 100s of feet.

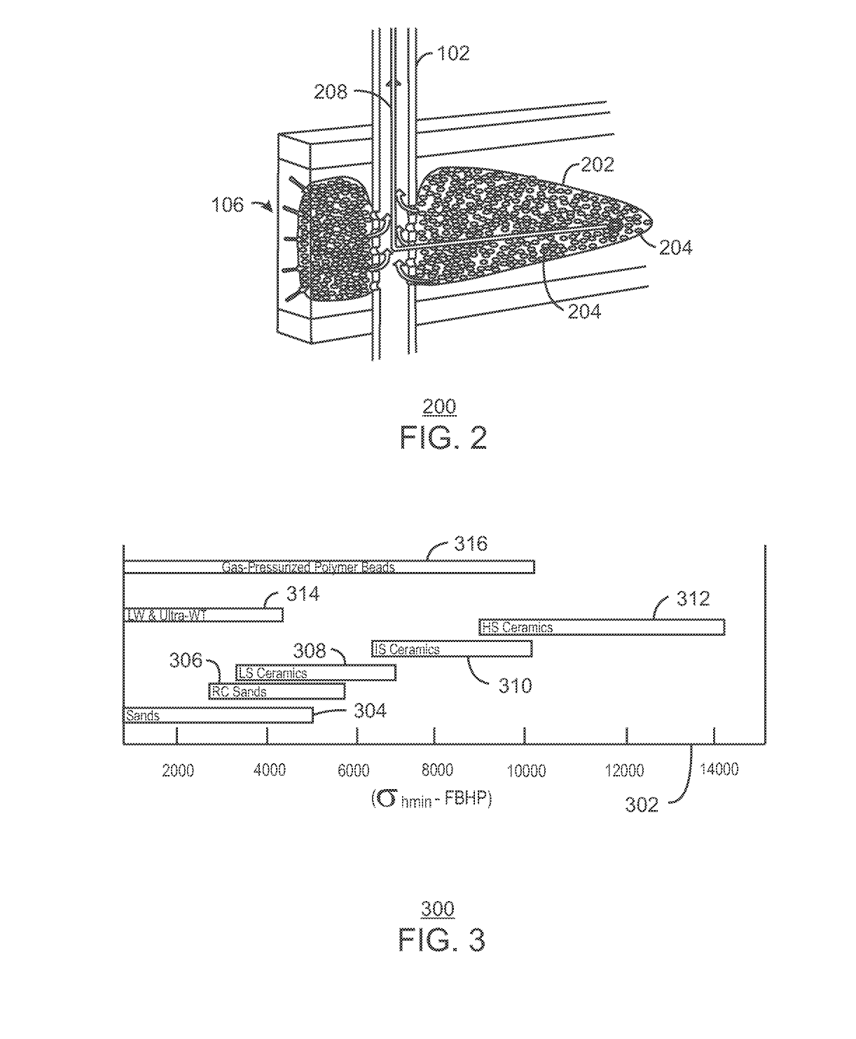

FIG. 2 is an expanded view 200 of a fracture 202 from a well 102, showing the placement of proppant particles 204 within the fracture 202. Like numbers are as described with respect to FIG. 1. The distance 206 that the proppant particles 204 travel in the fracture 202 can affect the amount of hydrocarbons 208 that can be harvested from the reservoir 106. In an embodiment, pressurized polymer beads are used as the proppant particles 204 and are substantially matched to the density of the fracturing fluid. As a result, the proppant particles 204 can travel much further into the fracture 202, allow hydrocarbons 208 to be harvested from a large section of the fracture 204, for example, from all directions in the length and height of the fracture.

### Proppants

FIG. 3 is a chart 300 comparing the strengths of various materials that may be used as proppants. In the chart 300, the y-axis 302 represents the in-situ closure stress on a proppant in PSI. The in-situ closure stress may be calculated as the difference between the minimum horizontal in-situ stress (σₕₘᵢₙ) and the flowing bottomhole pressure (FBHP). The in-situ closure stress 302 can be used to select proppants that have sufficient strength to resist crushing in fractures, e.g., the higher limit on each of the bars in the chart 300. Other factors may be used to select the lower limits on the chart, such as costs, density, and the like.

Sands 304 are standard proppants that are often used for comparison with other proppants. Sands 304 may be selected for wells having in-situ closure stress up to 5,000 psi. Resin coatings may extend the resistance to crushing, allowing sand to be used at in-situ closure stresses up to around 5,800 psi, as indicated by the bar labeled RC sands 306.

At still higher in-situ closure stresses, ceramic materials may be used as proppants. Low strength (LS) ceramics 308 may be used up to a in-situ closure stress of 7,000 psi. Although these proppants may be used at lower in-situ closure stresses, they become less practical at 3,500 psi, due to the presence of lower density and lower cost materials. At in-situ closure stresses up to 10,000 psi, intermediate strength (1S) ceramics 310 may be practical. The highest current in-situ closure stress resistance may be provided by high strength (HS) ceramics 312, which may be useful at in-situ closure stresses up to 14,000 psi.

All of the proppants 304-312 discussed above have density that is substantially greater than water ranging from 2.65 g/cc to 3.78 g/cc. Thus, they can sink when flow is slowed or stopped. Thus, these proppants 304-312 may only travel a short distance 206 (FIG. 2) in the fracture 202 before sinking, which may allow a portion of the fracture 202 to close and slow or stop the flow of hydrocarbons.

Lower density proppants have been developed which can travel a longer distance 206 in fractures 202. These proppants may be termed light weight (LW) and ultra weight (ultra-WT) proppants 314. However, the LW & Ultra-WT proppants 314 do not have sufficient strength for high stress applications and are limited to in-situ closure stresses of up to 4,200 psig.

In contrast to the prior materials discussed above, embodiments disclosed herein provide proppants that have a high strength and low density which may be used in wells having a wide range of in-situ closure stresses. These proppants are pressurized polymer beads 316, and may be useful for propping open fractures having in-situ closure stresses up to at least 10,000 psig. Variations of the pressurized polymer beads 316 may allow even higher pressures to be reached, for example, by allowing high internal pressures to be reached, as discussed in more detail below.

### Pressurized Polymer Beads

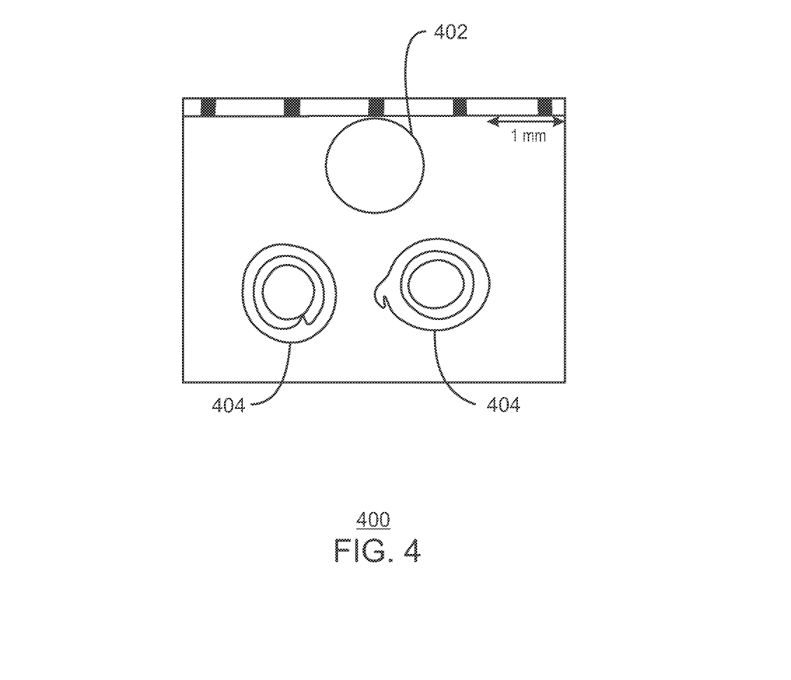

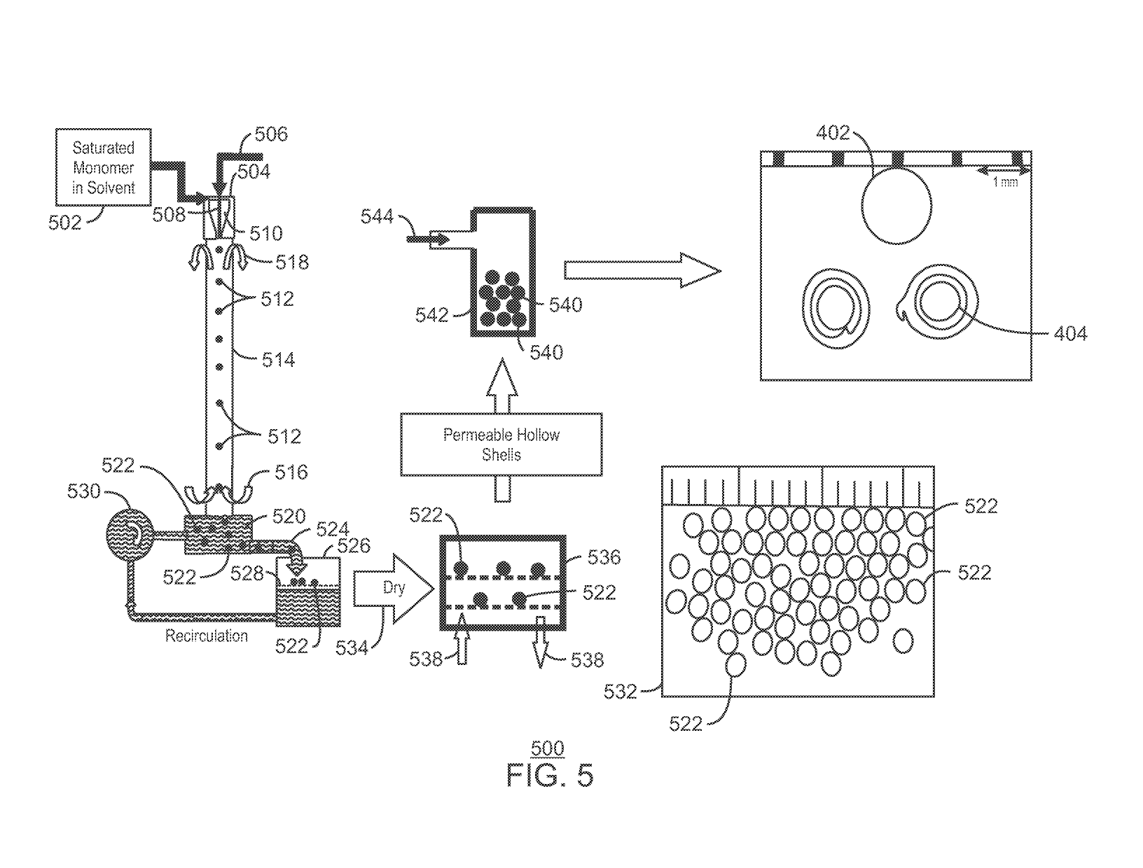

FIG. 4 is a drawing 400 of a pressurized polymer bead 402. The bead shown was generated with an internal pressure of 1500 psig, using the procedure discussed with respect to FIG. 5, below. The drawing 400 shows the interior of a pressurized polymer bead 402, which has been cut in two halves 404. The size of the pressurized polymer beads 402 can be accurately controlled in fabrication process. Therefore, a size distribution can be selected to balance the permeability and strength of proppants in fractures.

FIG. 5 is a schematic of a synthesis system 500 that may be used to form pressurized polymer beads 502. In an embodiment, the synthesis procedure used in the synthesis system 500 is a chemical imidization technique. Using the synthesis system 500, various types of pressurized polymer beads may be fabricated, including hollow polymer shells or structures having foamed cores.

In the synthesis system 500, a shell forming solution 502 is fed to a coaxial nozzle 504. The shell forming solution 502 may be any number of pure polymers or mixed polymers and monomers capable of forming a stable shell. In an embodiment, the shell forming solution 502 is a saturated solution of polyamic acid in a solvent. In other embodiments, the shell forming solution 502 may include soluble polymers or copolymers formed from pyromellitic dianhydride, 4,4′-oxydianiline, diisocyanates, diamines, dianhydrides, or any combinations thereof. The solvent used in the shell forming solution 502 may include any number of solvents, such as aromatic or aliphatic hydrocarbons, including both polar and non-polar solvents. In an embodiment, N-Methyl-2-pyrrolidone (NMP) is used as the solvents. In some embodiments, the solvents may include 1,3-Dimethyl-2-imidazolidinone (DMI), 2-Pyrrolidone (2-Pyrrolidinone, 2-Pyrol), N-cyclohexyl-2-pyrrolidone (CHP), and the like. The solvents are selected based on the solubility of the polymer, for example, polar solvents will generally be used for the polyamic acid, and the like. Other materials may be included in the shell forming solution 502 to modify the properties of the pressurized polymer beads. These materials may include reinforcement additives, such as carbon nanotubes or nanoscale ceramic particles of SiN, among others.

A second feed 506 to the coaxial nozzle 504 may include any number of fluids, such as a gas saturated with solvent, among others. As used herein, a fluid encompasses liquids, gases, and mixtures thereof. In some embodiments, the second feed 506 includes a monomer or polymer solution, for example, in a solvent that is immiscible with the solvent of the shell forming solution 502. This may be used to form a foamed inner core for a polymer bead, or to expand the polymer bead, among other purposes. The second feed 506 may also include foam cores that provide a template for the shell. Low density materials, such as alpha-polymethylstyrene, can be used as foamed core material. The solid shell material can be polyimide or any high strength and low gas permeability materials. The selection of core material focuses on low density if the material is different from sealing or structural material.

Sufficient differential pressure is independently applied within the annulus formed between an inner center tube 508 in the coaxial nozzle 504 and an outer coaxial tube 510 in the coaxial nozzle 504 to shape the shell forming solution 502 into hollow shells 512 that are filled with the fluid from the second feed 506. The hollow shells 512 detach from the coaxial nozzle 504 and drop into a tube 514. The hollow shells 512 may be a single polymer, or a mixture of polymers and monomers, depending on the combinations of polymers, monomers, and solvents introduced into the coaxial nozzle 504.

The tube 514 may be a drift tube configured to allow the hollow shells 512 to drift in a generally downward direction while drying. To slow the rate of downward drift, an injected gas 516, such as heated air, may be introduced at the bottom of the tube 514. The gas flows in a countercurrent stream to the hollow shells 512 and is removed as an exit gas stream 518 at the top of the tube 514. The tube 514 may be at a lower pressure than the second feed 506, allowing the hollow shells 512 to expand into a final shape and size. The expanded state of the hollow shells 512 may be predetermined by wall thickness, material mechanical properties, object architecture and internal pressure before, during or after cooling of the walls.

At the bottom of the tube 514, the hollow shells 512 can drop into a chemical bath 520. The chemical bath 520 contains reagents selected to harden the hollow shells 502 into hardened shells 522. The reagents may include reducing agents, oxidizing agents, or strong acids or bases that promote dehydration reactions in the surface of the hollow shells 512. These reagents may generally be termed imidization reagents, as they promote the ring closing reaction that forms a polyimide from a polyamic acid. Other reagents that may be used in the chemical bath include co-monomers, such as dianhydrides, among others. Other reagents may be used in the chemical bath 520, in place of or in addition to the imidization reagents. For example, the chemical bath 520 may include cross-linking agents, such as peroxides or other free radical initiators.

In an embodiment, the second feed 506 is eliminated and a nozzle 504 with a single tube, such as the center tube 508, is used. A solvent saturated polyamide acid is fed through the nozzle 504, forming a droplet, similar to the hollow shells 512. The hot gas 516 in the tube 514 helps to form a soft shell over the droplet. When the droplet lands in the chemical bath 520, a partially imidized bead 522 can be formed. If the chemical bath contains water bath, a bead 522 with a foamed core is formed as the solvent is rapidly extracted into the water.

The tube 514 may be filled with a liquid instead of a gas, in which the separation of the hollow polymer spheres 512 may be caused by surface tension, gravity, buoyancy, fluid flow or any combination thereof. For example, in this arrangement the coaxial nozzle 504 may be placed at the bottom of the tube 514. An immiscible fluid containing an imidization reagent may be layered over the liquid. For example, the liquid may be an organic solvent that extracts the dissolution solvent from the hollow shell 512, hardening the hollow shell 512. As the hollow shell 512 continues to float upwards, it can cross a phase transition into an aqueous phase that includes the strong acid or base that forms the hardened shells 522. This arrangement may also be useful for creating additional layers on the hardened shells 522.

The hardened shells 522 may be swept out of the chemical bath 520 through a transfer line 524 and into a drying chamber 526. The drying chamber 526 may include a screen 528, which allows the beads to be separated from the solution. The solution may then be returned to the chemical bath 512 through a pump 530. The hardened shells 522 may then be removed from the drying chamber 526, for example, through a pressure interlock chamber (not shown). The hardened shells 522 may be transparent, as shown in the drawing 532, as the partial imidization is not sufficient to make the hardened shells 522 turn black.

As indicated by an arrow 534, the hardened shells 522 may be transferred to an oven 536, in which the hardened shells 522 may be dried. This may be performed by circulating air 538 through the oven 536 while keeping the hardened shells 522 at 50° C. Generally, the temperature will be kept below 100° C. to prevent full imidization. The drying process creates permeable hollow shells 540.

If the polymer wall is the load bearing member, expansion of the diameter of the hardened shells 522, such as by pulling a slight vacuum on the drying oven 536, may be used to alter the mechanical properties of the polymer wall. For example, the properties may be changed by strain re-orientation of the polymer chains and/or re-orientation of a reinforcement in the polymer wall of the hardened shells 522 as the permeable hollow shells 540 are formed. The permeable hollow shells 540 are then transferred to an autoclave 542.

In the autoclave 542, the pressure is increased by the addition of a gas 544 until a final pressure is reached. For example, the pressure may be increased by the addition of nitrogen, SF₆, argon, CO₂, or any other gases or gas combinations. The pressure increase may be done over a time interval of a few minutes to a few hours to allow the gas to diffuse into the permeable hollow shells 540 and equalize, avoiding collapsing the permeable hollow shells 540. If a very thick wall is used, the diffusion rate may be too slow for effective pressurization. In this case, a thinner layer of polyimide may be used with a structural material to provide strength. This is discussed further below.

Once the pressure in the autoclave 542 has reached a final target pressure, the temperature can be raised to around 200-300° C. to complete the imidization reaction in the permeable hollow shells 540, forming the pressurized polymer beads 402. The gas 544 that has diffused into the permeable hollow shells 540 is trapped in the pressurized polymer beads 402. If the core of the bead is formed from a foamed, low density polymer, the core may melt during high temperature thermal imidization. To avoid this, room temperature chemical imidization can be used after proppants are pressurized by the diffusion method.

The pressurized polymer beads 402 can be fabricated using various other methods such as a liquid/gel droplet methods, emulsion polymerization methods, coating on template methods, and the like. For example, the chemical bath 520 may include water with an imidizing agent. A diffusion mechanism may be used to extract solvent out to form hardened shells 522 with a foamed core. Those hardened shells 522 are dried and pressurized by nitrogen in an autoclave and then fully imidized at high temperature with nitrogen present, as described above.

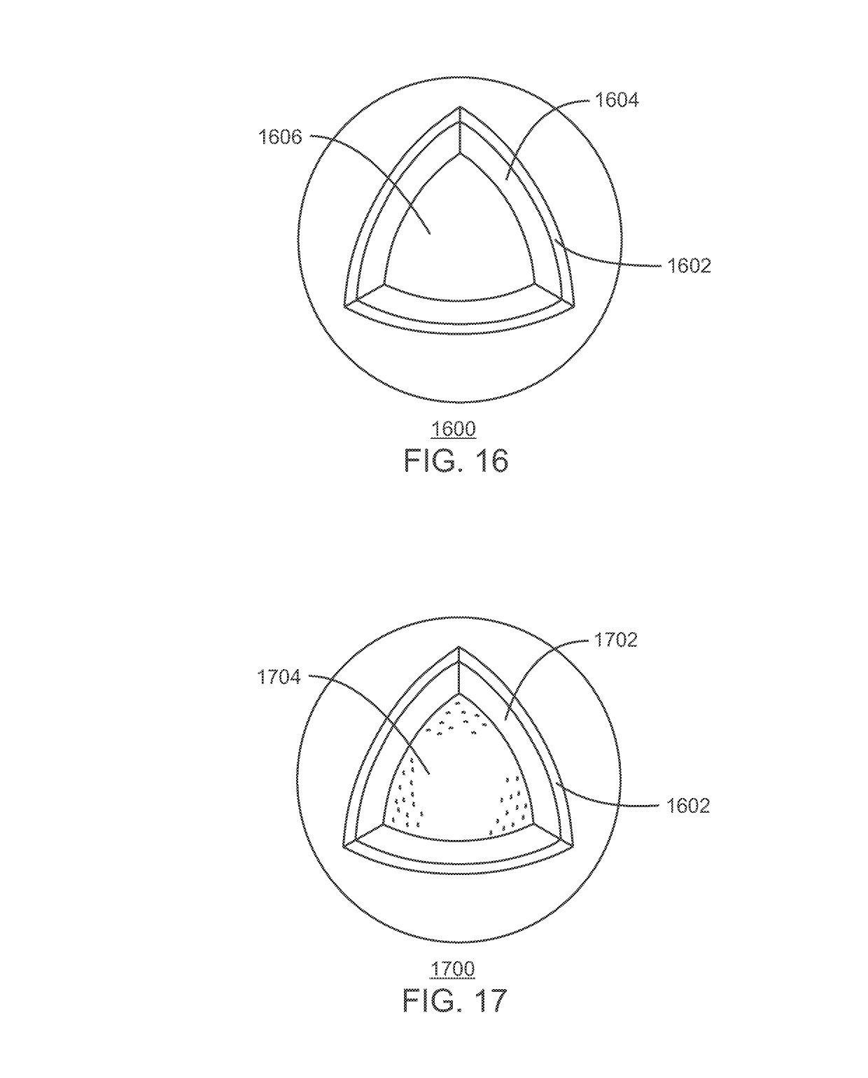

In another method that can be used in embodiments, a polyamic acid is coated on beads made of poly (alpha-methyl styrene), for example, using vapor deposition. The poly(alpha-methyl styrene) beads act as a template for forming a polyimide bead. The poly(alpha-methyl styrene) template can be made using a liquid/gel droplet method, an emulsion polymerization method, or any number of other methods know in the art. Vapor deposition method can be used to coat the polyamic acid on the surface of templates. By thermal treatment, the poly (alpha-methyl styrene) can be depolymerized and extracted from the polyamic shells. The resulting hollow polyamic acid shells are oven dried and then pressurized by nitrogen in an autoclave. Heating to 200° C. to 400° C. in the autoclave under the nitrogen pressure then completes the imidization reaction. Materials can always be coated on the surface of the pressurized polymer beads 402 to provide special functions, as described with respect to FIGS. 16-23.

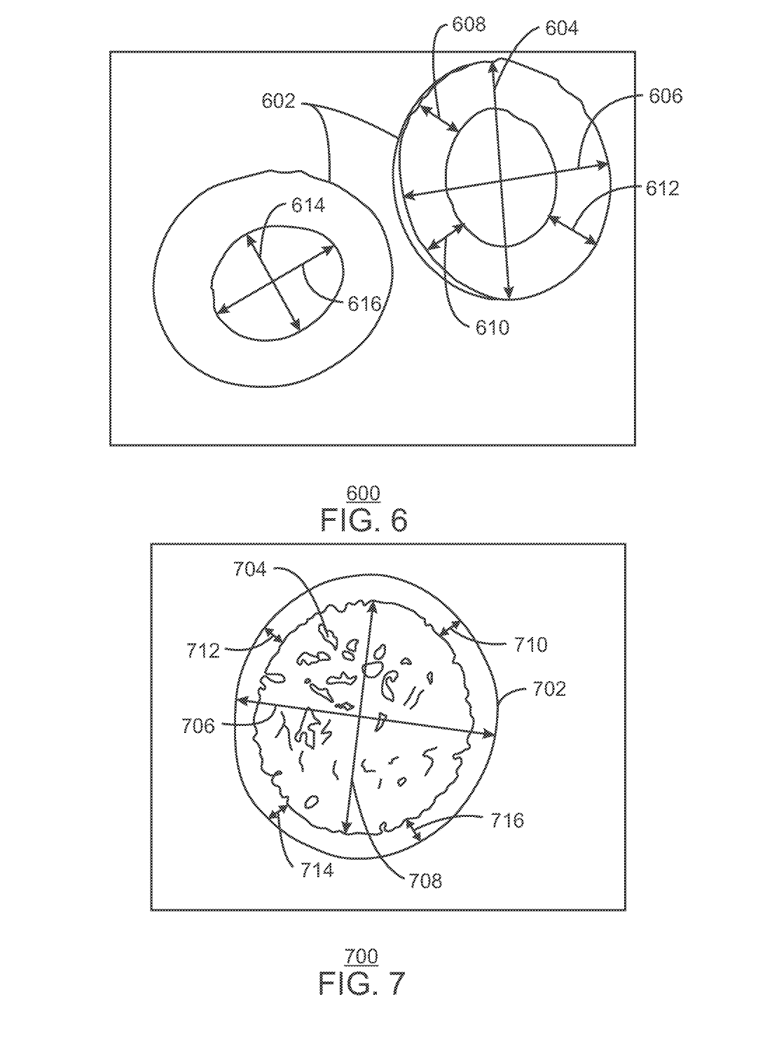

FIG. 6 is an electron micrograph 600 of a pressurized polymer bead 602 with a hollow core, which has been sectioned to show the wall dimensions. As can be seen from the electron micrograph 600, the pressurized polymer bead 602 is not perfectly spherical, having a first dimension 604 of 0.979 mm and a second dimension 606 of 0.846 mm. The wall thickness at a first point 608 is 201 μm, at a second point 610 is 183 μm, and at a third point 612 is 219 μm. The inner diameter at a first point 614 is 0.455 mm, and at a second point 616 is 0.561 mm.

FIG. 7 is an electron micrograph 700 of a pressurized polymer bead 702 with a foamed core 704, which has been sectioned to show the dimensions. The pressurized polymer bead 702 with a foamed core 704 is more nearly spherical than the pressurized polymer bead 602 with the hollow core. The outer diameter 706 is 1.294 mm. The diameter 708 of the foamed core 704 is 1.167 mm. The wall thickness was measured at four points, with a first point 710 measuring 112 μm, a second point 712 measuring 105 μm, a third point 714 measuring 108 μm, and a fourth point 716 measuring 111 μm.

The polymer beads shown in FIGS. 6 and 7 are merely exemplary. Other beads may be larger or smaller and may have more or less regularity. The wall thicknesses may be adjusted to assist in retaining the internal pressure as well as to adjust the density of the pressurized polymer beads. The highly impermeable shell can extend the life of the pressurized polymer beads, making their use as proppants practical.

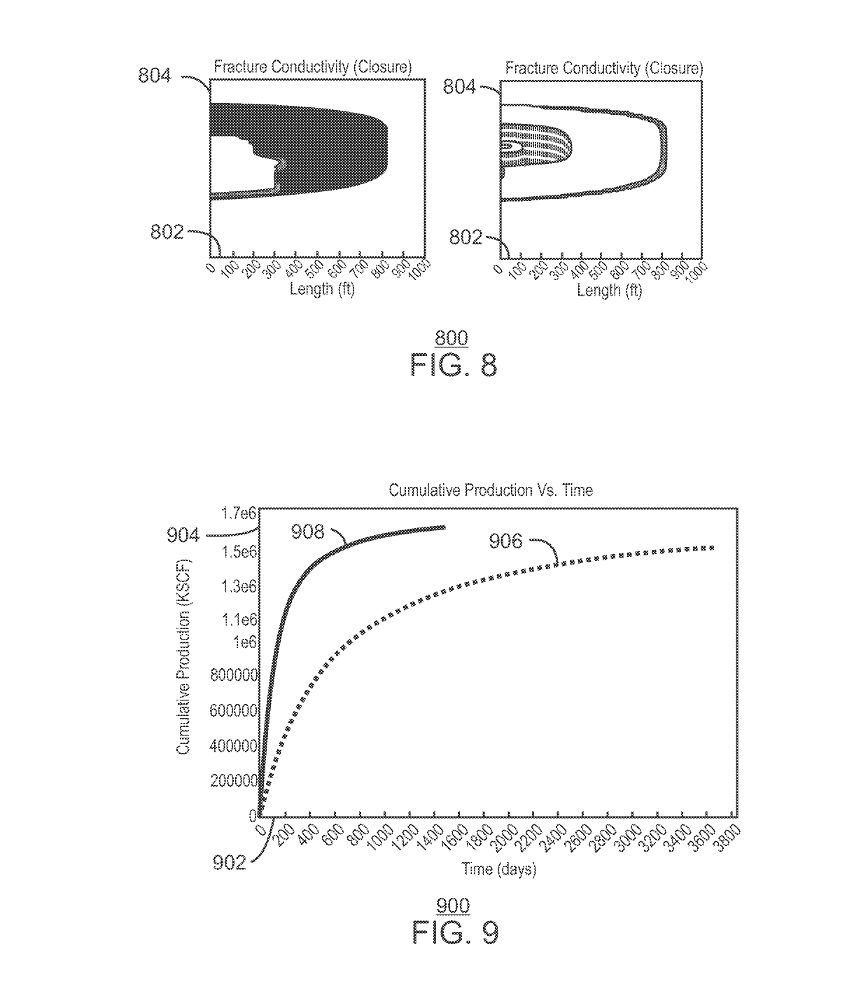

For example, the effective lifetime of a pressurized polymer bead may be limited by gas leakage through the wall. In the case of a pressurized polymer bead formed from the crystalline polymer poly(ether-ether ketone) (PEEK), the gas permeation rate for oxygen for a differential pressure of 1 atm is approximately 852.5 cm³/day m² for a 100 micron thick wall at 25° C. By comparison, the pressurized polymer beads formed from polyimides, as described herein, have an oxygen leakoff rate of 0.8 cm³·mil/m²·day·atm at 30° C., over 1000 times lower than PEEK. Thus, the polyimide beads may retain internal gas pressures for longer periods and, thus, may be more functional as proppants in fracturing applications. The low density provides buoyancy which assists in prevent settling of the beads in fractures, as discussed further with respect to FIG. 8.

FIG. 8 are plots 800 of a simulation of travel distance in a propped fracture for a conventional Brady sand in comparison to the low density, pressurized polymer beads. The x-axes 802 represent the travel distance in feet, while the y-axes 804 represents the height within the fracture. As shown in FIG. 7(A), numerical simulations predict that conventional Brady sands can reach only 37% in propped fracture length (100 m of a 275 m long fracture) and 65% in propped fracture height. In contrast, as shown in FIG. 7(B), the more buoyant pressurized polymer beads, disclosed herein, can reach 100% in propped fracture length and height. Fully propped fractures can increase the production of hydrocarbons, as mentioned previously. The comparison of the cumulative production from the two simulations is discussed with respect to FIG. 9.

FIG. 9 is a plot 900 of cumulative production from a reservoir. The x-axis 902 represents the time from the start of production in days, while the y-axis 904 represents the cumulative production of a reservoir. A first plot indicates a cumulative production 906 for the partially propped fracture discussed with respect to FIG. 8(A). A second plot indicates a cumulative production 908 for the fully propped fracture, discussed with respect to FIG. 8(B). The partially propped fracture has a cumulative production 906 of 1.5 billion cubic feet (bcf) of natural gas in 3400 days. In contrast, the fully propped fracture has a cumulative production 908 of 1.6 bcf in 1400 days, indicating a much higher rate of recovery. As indicated by the comparison, the full coverage of the fractured area leads to more efficient production of hydrocarbons from a reservoir. In addition, the more efficient coverage indicates that the amount of proppants in the fracturing fluid may be decreased providing better economics.

Further, the low density (high buoyancy) of the pressurized polymer beads makes them practical to use in both shallow and deeper wells, e.g., under conditions of both low and high in-situ closure stresses as discussed with respect to FIG. 3. The polyimides used are stable at high temperature and can be produced at any desired sieve distribution. Since lighter weight proppants are used, less damage to the formation may be expected, and therefore more well production can be achieved.

### Modeling of Stresses on Polyimide Beads

The load capacity of a pressurized polymer bead depends on the compressive forces required to keep the fracture open, balanced against the external hydrostatic pressure inside fractures. The determination may be performed using non-linear finite element analysis. The application of external compressive forces to proppants is unpredictable, but simplifications may be used.

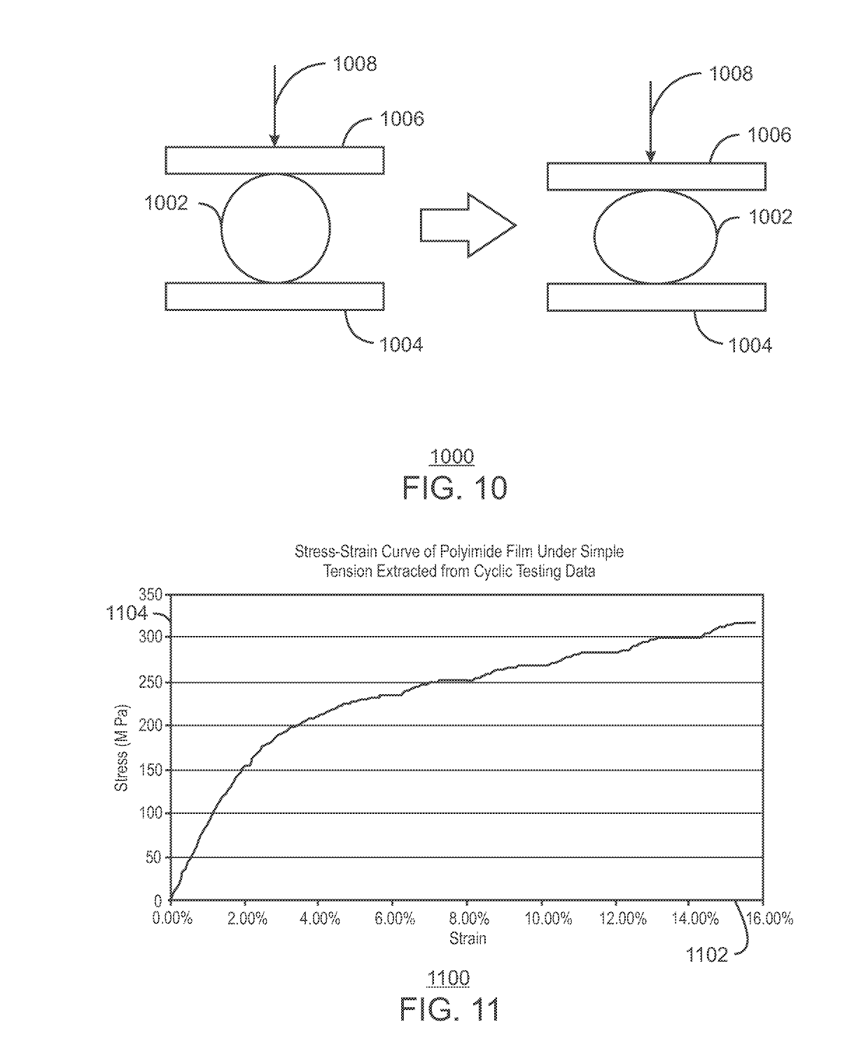

FIG. 10 is a drawing 1000 of a pressurized polymer bead 1002 compressed between two parallel rigid platens 1004 and 1006. The bottom platen 1004 may be fixed, while the top platen 1006 may be moved towards the bottom platen 1004, as indicated by an arrow 1008. This example represents one of most severe loading cases, as the pressurized polymer bead 1002 is subjected to a bi-lateral extension without lateral support. By comparison, in an API crush test, API No. RP-56, proppants are compressed in a closed boundaries and there are lateral supports to each individual proppant. This example corresponds to a deformation of 0.25 times the radius (0.25r) of the pressurized polymer bead 1002, which can be used as standard point for estimating the load capacity of an proppant. The load capacity for an individual pressurized polymer bead 1002 can be estimated by the reaction force of the compression, shown in the drawing, divided by the nominal cross-section area, πr², of the pressurized polymer bead 1002.

The pressurized polymer beads 1002 are more flexible than fully solid proppants, such as those made out of ceramic. Therefore, a large deformation in the shell structure is expected in order to reach the maximum load capacity. Stress based failure criteria can be hard to establish experimentally for three-dimensional deformation. Therefore, strain based failure criteria are useful for designing the pressurized polymer beads 1002 described herein.

The strain based failure criteria include the qualifications that the maximum strain ε₁ and the maximum value of first invariant I₁ of the strain tensor are less than the corresponding experimental values for ε₁^{o} and I₁^{o}, when the average contact pressure, using the apparatus of FIG. 10, reached the ultimate compressive strength of the reservoir rock at in-situ reservoir conditions. This occurs when the conditions of Eqn. 1 are met.

$${ɛ}_{1} < \frac{{ɛ}_{1}^{o}}{α} \\ {I}_{1} = {ɛ}_{1}^{2} + {ɛ}_{2}^{2} + {ɛ}_{3}^{2} < \frac{{I}_{1}^{o}}{α} = \frac{{( {ɛ}_{1}^{o} )}^{2} + {( {ɛ}_{2}^{o} )}^{2} + {( {ɛ}_{3}^{o} )}^{2}}{α} \qquad Eqn . 1$$

In Eqn. 1, εᵢ are the principal strains, and α is the safety factor. A value for α can be determined by lab tests, e.g., as a combination of the material property change due to temperature, stress relaxation, creep and plus a safety margin. In Eqn. 1, α will be selected to be greater than one.

FIG. 11 is a plot 1100 of a tension test on a piece of polyimide film of the same composition as the pressurized polymer beads. The x-axis 1102 represents the strain (elongation) in %, and the y-axis 1104 represents the stress in megapascals (MPa). This test can be used to experimentally determine values for ε₁^{o} and I₁^{o}, which may be used in Eqn. 1. For example, in a simple tension testing using MTS, ε₁^{o} is the strain at break and I₁^{o} can be calculated from ε₁^{o} using the assumption of simple tension and setting Poisson's ratio to be equal to 0.5

Increasing the efficiency of material usage can reduce the weight of the pressurized polymer bead. The efficiency of material usage can be calculated as the work required to create a 0.25r displacement under the loading condition discussed above. The loading condition can be used in determining the load capacity by dividing by the bulk volume of a proppant.

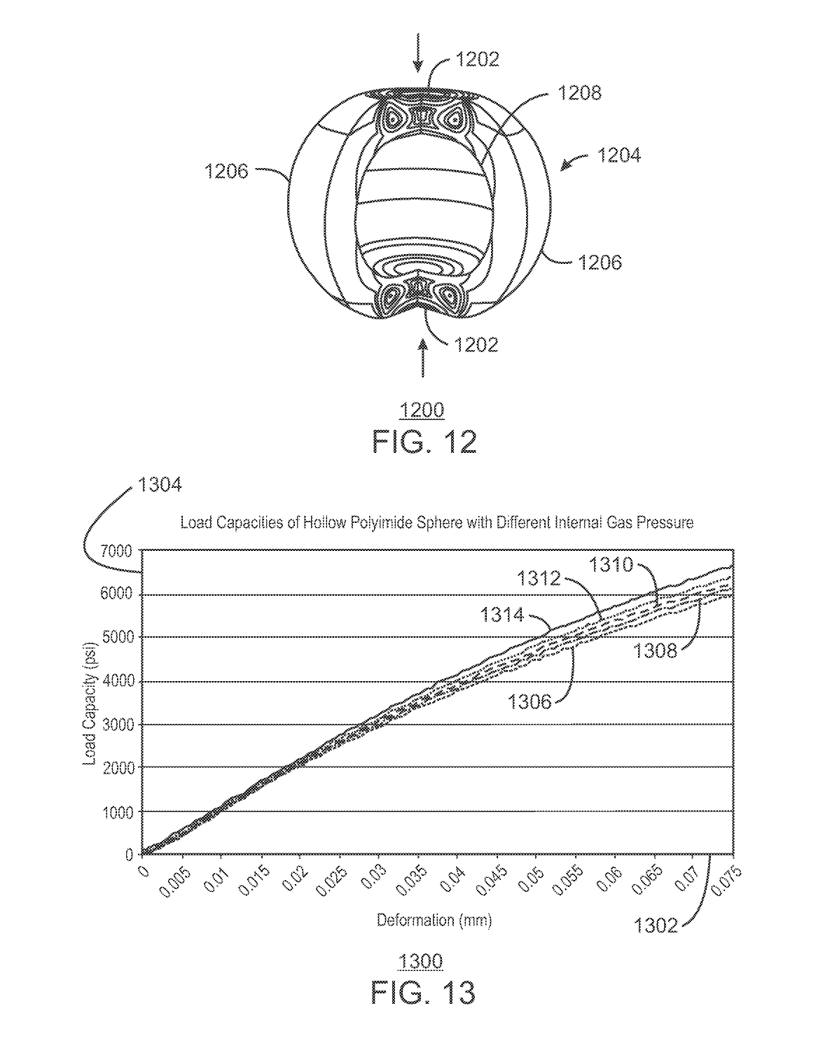

FIG. 12 is a drawing of a stress distribution 1200 on a pressurized polymer bead calculated by finite element analysis (FEA) for a pressurized polymer bead under the loading condition of FIG. 10. The pressurized polymer bead is under a 0.25r compression. The stress distribution 1200 result shown in FIG. 12 is a maximum nominal principal strain. The pressurized polymer bead 1202 is 1 mm in diameter, 0.154 mm in wall thickness, and with 1500 psi internal pressure. As shown, the highest stress regions 1202 are at the contact points of the pressurized polymer bead 1204 with the platens 1004 and 1006. The lowest stress region 1206 is along the outside of the pressurized polymer bead 1202, and higher stresses are distributed along the inner wall 1208 of the pressurized polymer bead 1202.

FIG. 13 is a plot 1300 of the load capacities of a pressurized polymer bead. The load capacities are predicted by nonlinear finite element analysis as discussed above. In the plot 1300, the x-axis 1302 represents a deformation of the pressurized polymer bead in mm, while the y-axis 1304 represents the load capacity of the pressurized polymer bead in psi. For purposes of this calculation, a pressurized polymer bead was assumed to be 1 mm in diameter and have a wall thickness of 0.154 mm in wall thickness. Further, the pressurized polymer bead was assumed to be made from a polyimide, and to have different internal gas pressures. The internal gas pressures used for the calculations in the plot 1300 were 0 psi 1306, 1,500 psi 1308, 3,000 psi 1310, 5,000 psi 1312, and 10,000 psi 1314. As can be seen in the plot 1100, the load capacities show an increase as the internal pressure is increased.

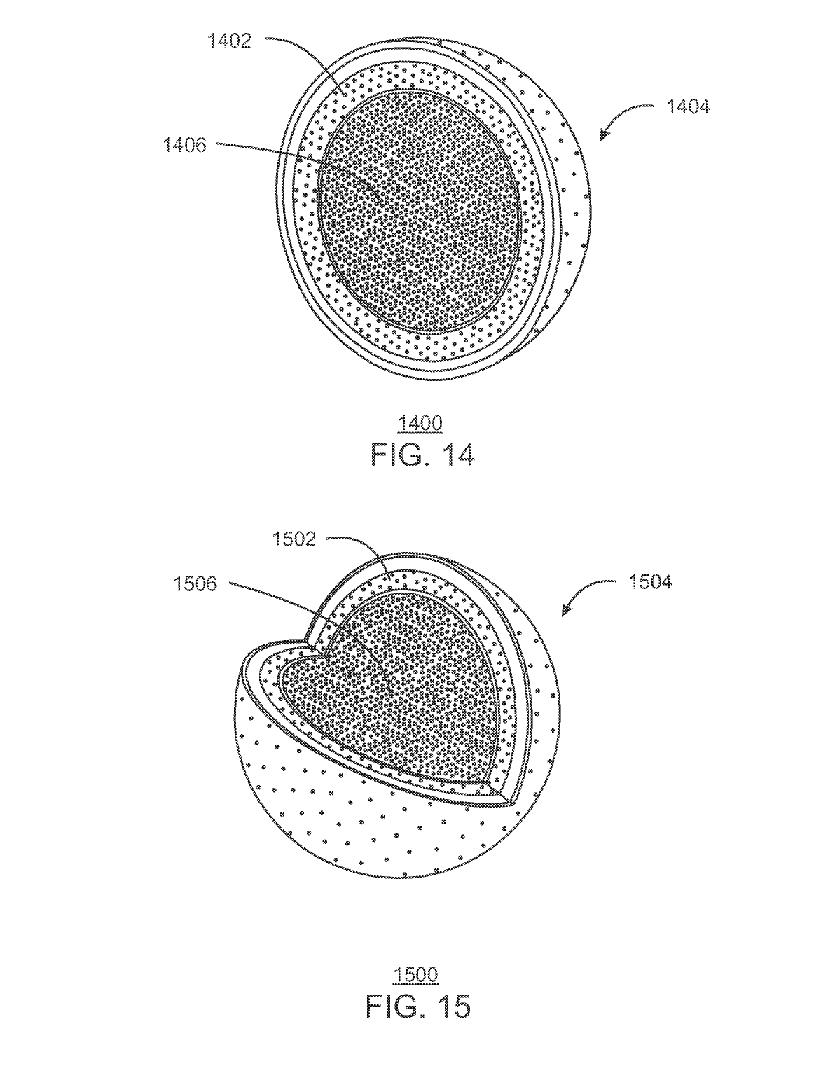

The results for the loading on the pressurized polymer bead by the platens may be compared to the stresses placed on the shell under more even loading as discussed with respect to FIG. 14. Even when no external loading is applied, the internal pressure of a pressurized polymer bead places loading on the shell, as discussed with respect to FIG. 15.

FIG. 14 is a drawing of a stress distribution 1400 on a pressurized polymer bead calculated by finite element analysis (FEA) for 100 MPa (14,504 psi) external pressure with no internal pressure. The stress distribution 1400 was obtained using nonlinear finite element analysis of a pressurized polymer bead having a 1 mm diameter polyimide shell and a 0.125 mm wall thickness. As can be seen, the highest level of stress is in the layer 1402 of the shell 1404 nearest the hollow core 1406.

FIG. 15 is a drawing of a stress distribution 1500 on a pressurized polymer bead calculated by finite element analysis (FEA) when the pressurized polymer bead experiences free expansion under 15,000 psi internal gas pressure. As in the previous models, the FEA results indicated that the highest level of stress is in the layer 1502 of the shell 1504 nearest the hollow core 1506.

### Methods for Designing Pressurized Polymer Beads as Proppants

The pressurized polymer beads can be designed to have a diameter between 0.5 mm and 1 mm to enhance the fluid conductivity in the fractures in comparison to larger pressurized polymer beads. A diameter in this range may also provide better rheology than larger pressurized polymer beads in the mixture of hydraulic fracturing fluids and proppants. However, the pressurized polymer beads are not limited to this size range and can be manufactured in larger sizes, such as less than 2 mm, less than 5 mm, and larger. However, it can be noted that the pressurized polymer beads have to pass through a pump system and into the fracture. Thus, the size may be limited by the pump system and the widths of the fracture opening.

The wall thickness of a pressurized polymer bead can be determined by a target specific gravity. For a pressurized polymer bead with a hollow shell, the wall thickness can be determined by Eqn. 2

$$t = r ( 1 - \sqrt[3]{1 - \frac{{ρ}_{o}}{ρ}} ) \qquad Eqn . 2$$

In Eqn. 2, r represents the external radius of the proppant, ρ is the density of wall material and ρₒ is the target proppant density. For example, a pressurized polymer bead 402, such as shown in FIG. 4, can be made of a polyimide material with density of 1.42 g/cc. If the target proppant has a radius r=0.5 mm and density of 0.95 g/cc, the target wall thickness will be =0.154 mm.

### Modified Pressurized Polymer Beads for Use as Proppants

Any number of structures of the pressurized polymer beads can be used as proppants. For example, the pressurized polymer beads 602 of FIG. 6 may be used. As discussed with respect to FIG. 6, these pressurized polymer beads include a hollow shell forming a pressurized cavity. The hollow shell functions as both a structural support and a sealing material, i.e., to keep the pressurized gas in the core. In the pressurized polymer beads 702 of FIG. 7, a pressurized foamed core is in the center of the shell. As for the pressurized polymer beads 602 having a hollow shell, the shell functions as both a structural support and a sealing material. Any number of other configurations may also be used as proppants, as discussed with respect to FIGS. 16-23.

FIG. 16 is a drawing of a pressurized polymer bead 1600 having a protective coating 1602 as an outside layer over a hollow shell 1604 enclosing a pressurized cavity 1606. The hollow shell 1604 functions both as a structural support and a sealing material. The protective coating 1602 may make the pressurized polymer bead 1600 more resistant to damage, for example, from abrasion, pumping, and the like. Any number of materials may be used as the protective coating 1602 including polymers, linear hydrocarbons, and surfactants, among others.

Polymers that may be used as the protective coating 1602 include poly (ether-ether-ketone) (PEEK), polyphenylene sulfide (PPS), elastomers, epoxides, polysiloxanes, or polyurethanes, among others. The polymers can be applied by any number of techniques known in the art. Such techniques can include placing the fully imidized pressurized polymer beads in a polymer melt. Other techniques, such as spraying polymer precursors onto the pressurized polymer beads, and then polymerizing the precursors, may also be used. Further, the polymers may be formed over a foamed core and added to the second feed 506, to be used as a template for forming the pressurized polymer beads.

Other methods may be used to apply the protective coating 1602. For example, the pressurized polymer beads and coating materials may be passed through high frequency vibrating co-axial nozzles into heated gas column to dry the coating. The coating thickness can be controlled by the relative injection rate between the coating materials and the pressurized polymer beads. In another technique, the pressurized polymer beads and coating materials may be injected through a high speed rotating disk. The disk may have radially open slots, and the mixture of pressurized polymer beads and coating materials moving out radially from the disk can be injected under centripetal force into a heated gas dry chamber. The coating thickness may be controlled by the rotating speed, in which the difference in inertial separates coating material from pressurized polymer beads. Further, the pressurized polymer beads may be coated by an air suspension coating method using top spray coater, Wurster bottom coater, and the like.

The protective coating 1602 can be designed for special functions, such as making the pressurized polymer beads more chemically compatible with the chemicals used in hydraulic fracturing fluids, such as by attaching surfactants to the outside of the shell. The protective coating 1602 may also prevent chemical attack from weakening the pressurized polymer beads. Other protective coatings 1602 may be used to preventing the pressurized polymer beads from aggregating together during injection, reducing viscosity in the mixture of proppants and hydraulic fracturing fluids, and the like.

FIG. 17 is a drawing of a similar pressurized polymer bead 1700 having a protective layer 1602 over a shell 1702 that holds a pressurized foamed core 1704. As for the pressurized polymer bead 1600 of FIG. 16, the shell 1702 functions as both a structural support and a sealing material.

In some applications, it may be desirable to slow a gas leakage rate over that provided by the shell alone. This may be done by the formation of a sealing layer. A sealing layer may also protect the polyimide of the shell from weakening or attack from external solvents or reagents.

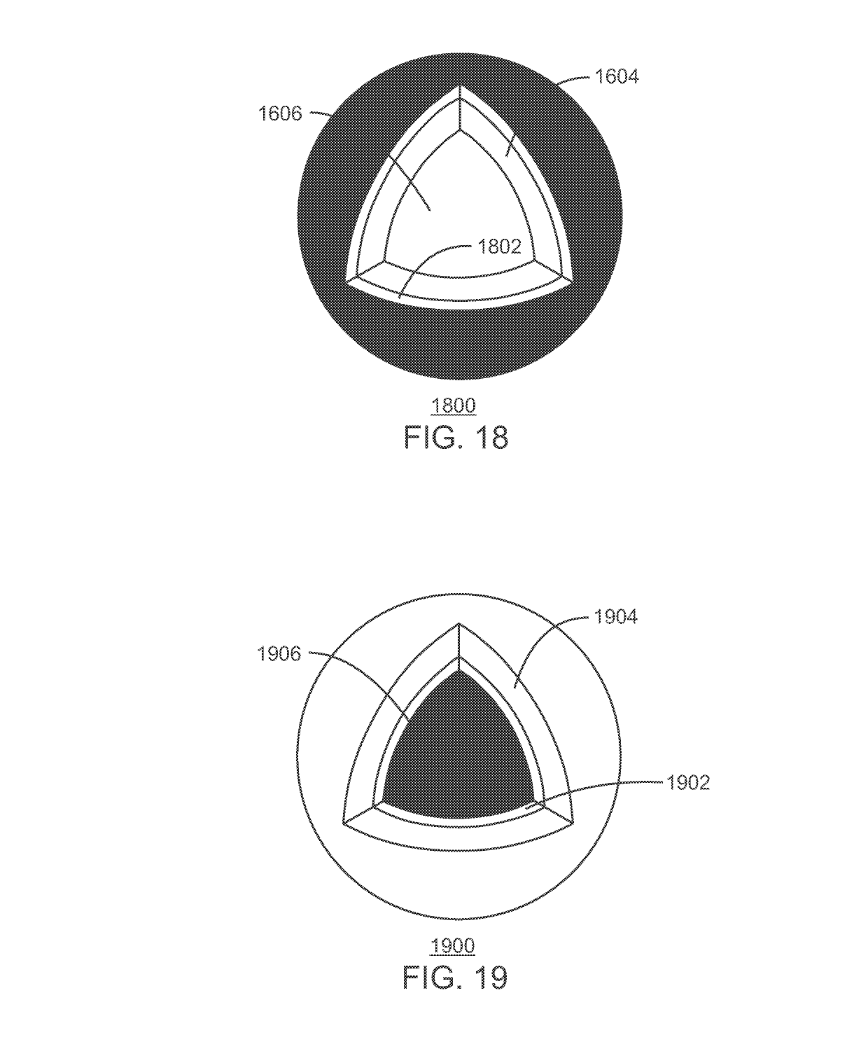

FIG. 18 is a drawing of a pressurized polymer bead 1800 having a sealing layer 1802 over a hollow shell 1604 that encloses a pressurized cavity 1606. The sealing layer 1802 can be a metal film, which may be applied to the pressurized polymer bead by vapor or chemical deposition. Other materials may be selected as the sealing layer 1802, for example, to protect the polyimide from external solvents or additives. Further, the sealing layer 1802 may be a polyimide layer formed over a hollow shell 1604 made from a different material. For example, the hollow shell 1604 may be made from polypropylene, PEEK, PPS, or other materials. In the pressurized polymer bead 1800, the hollow shell 1604 functions as a structural support, while the sealing layer 1802 further slows diffusion through the hollow shell 1604. The sealing layer may be formed along the internal surface of the structural shell.

FIG. 19 is a drawing of a pressurized polymer bead 1900 having a sealing layer 1902 formed along the inside surface of a hollow shell 1904. The hollow shell 1904 functions as a structural support, while the sealing layer 1902 slows the diffusion of gas from the pressurized center 1906. For example, the hollow shell 1904 may be made from a polypropylene, a PEEK, a PPS or another polymer material, while the sealing layer 1902 is formed from a polyimide layer. Any number of other combinations of these features is possible.

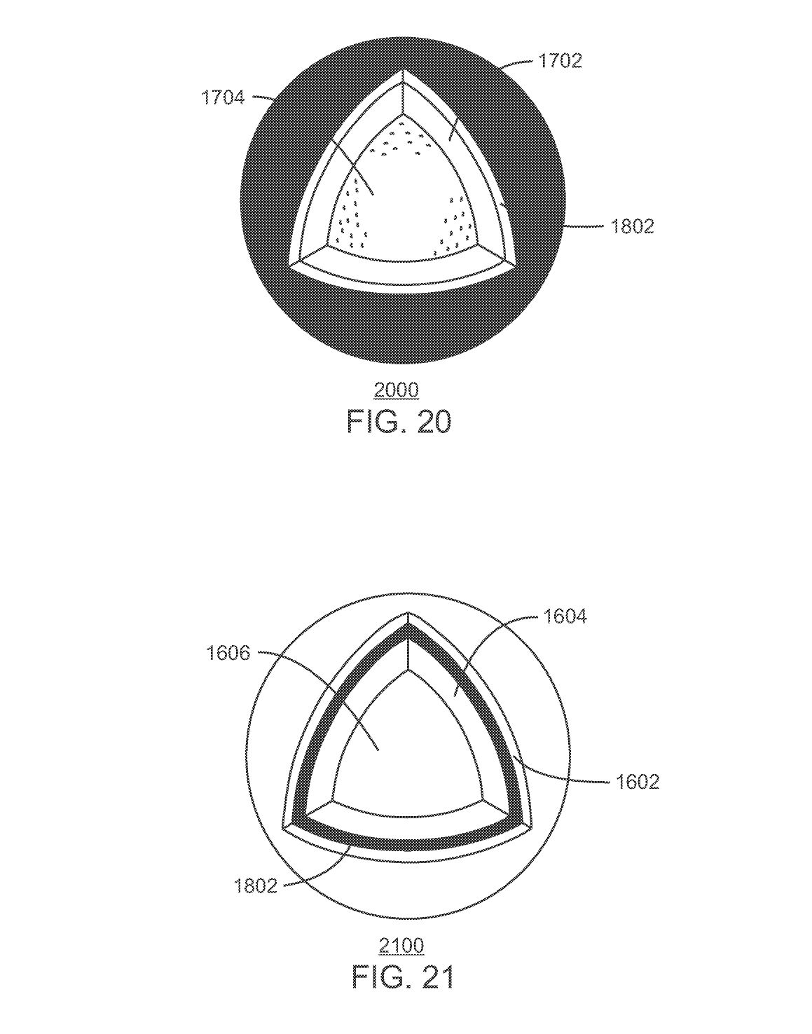

FIG. 20 is a drawing of a pressurized polymer bead 2000 having a sealing layer 1802 over a shell 1702 that holds a pressurized foamed core 1704. Like numbered items are as described above. The shell 1702 provides structural support, while the sealing layer 1802 may be used to slow the diffusion of gas out of the pressurized foamed core 1704.

FIG. 21 is a drawing of a pressurized polymer bead 2100 having a sealing layer 1802 over a hollow shell 1604 enclosing a pressurized cavity 1606, in which a protective coating 1602 forms an outside layer over the sealing layer 1802. Like numbers are as described above. The hollow shell 1604 functions as the structural support, while the sealing layer 1802 slows the diffusion of gas out of the pressurized cavity 1606. The protective coating 1602 can prevent damage to the sealing layer 1802, increasing the lifespan of the pressurized polymer bead 2100.

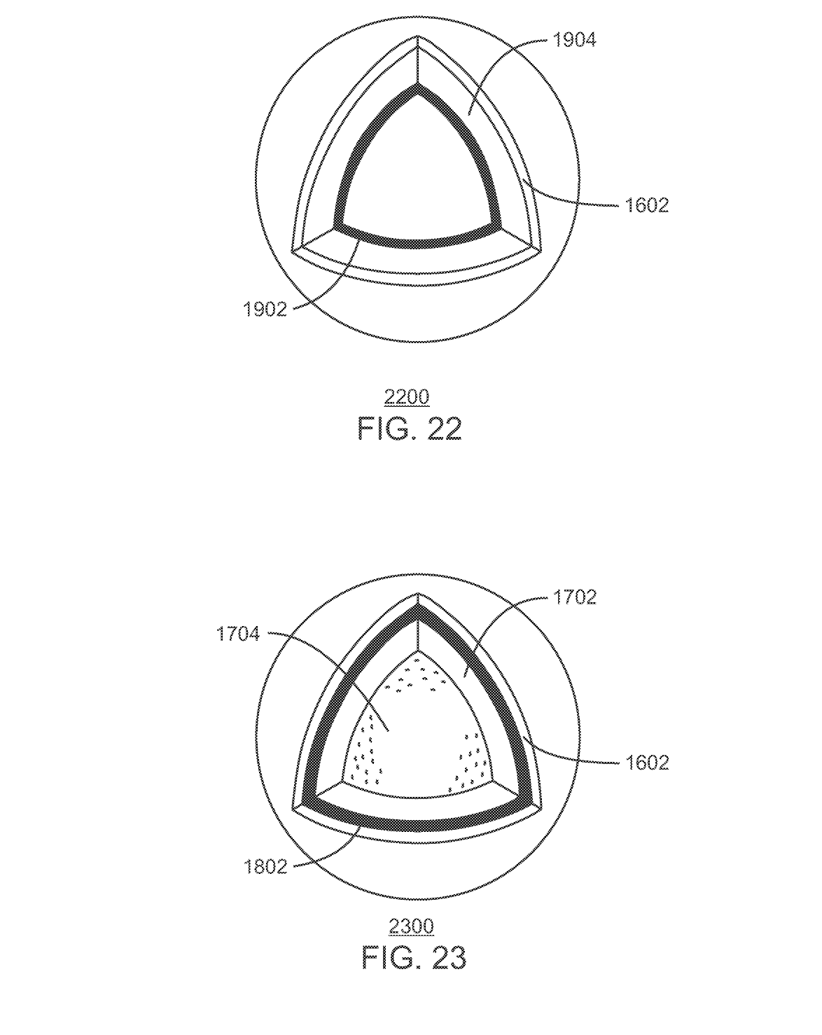

FIG. 22 is a drawing of a pressurized polymer bead 2200 having a sealing layer 1902 formed along the inner surface of a hollow shell 1904, with a protective coating 1602 as an outside layer over the hollow shell 1904. This pressurized polymer bead 2200 would function in a similar fashion to the pressurized polymer bead 2100 of FIG. 21.

FIG. 23 is a drawing of a pressurized polymer bead 2300 having a sealing layer 1802 applied over a shell 1702 that includes a pressurized foamed core 1704, with a protective coating 1602 applied over the sealing layer 1802. Like numbers are as described above. The shell 1702 provides structural support, while the sealing layer slows the diffusion of gas from the pressurized foamed core 1704. The protective coating 1602 protects the sealing layer 1802 from damage.

While the present techniques may be susceptible to various modifications and alternative forms, the exemplary embodiments discussed above have been shown only by way of example. However, it should again be understood that the techniques is not intended to be limited to the particular embodiments disclosed herein. Indeed, the present techniques include all alternatives, modifications, and equivalents falling within the true spirit and scope of the appended claims.

### Embodiments

1. An embodiment described herein provides a pressurized polymer bead for use as a proppant in hydraulic fracturing, including: a shell that is substantially impermeable, wherein the shell comprises a polyimide polymer; and a core region at a pressure that is at least (not less than) 5 Mpa.

2. The polyimide polymer in embodiment 1 can be formed using pyromellitic dianhydride, 4,4′-oxydianiline, diisocyanates, diamines, dianhydrides, or any combinations thereof.

3. The core region in embodiment 1 can include a gas, a liquid, or a combination thereof.

4. The core region in embodiment 1 can include a gas mixed with a damage removal fluid.

5. The damage removal fluid of embodiment 4 can include an oxidizer, an acid, an enzyme, or any combinations thereof.

6. The core region in embodiment 1 can include a foamed polymer.

7. The shell in embodiment 1 can have an outer layer and an inner layer.

8. The outer layer in embodiment 7, can include a metal film, or a polymer, or both.

9. The polymer in embodiment 8 can include a polyolefin, a poly (ether ether ketone) (PEEK), a styrenic polymer, a poly(phenylene sulfide), an elastomeric polymer, or multiple layers thereof.

10. The inner layer in embodiment 7 can include a polyimide layer.

11. The pressurized polymer bead in embodiment 1 can include an inner layer disposed on the inside surface of the shell and an outer layer disposed on the outer surface of the shell.

12. A thickness for the shell in embodiment 1 can be configured to substantially match the density of the pressurized bead to a carrier fluid.

13. The pressurized polymer bead of embodiment 1 can be between 0.5 millimeter in diameter and 1 millimeter in diameter.

14. The pressure of the core region in embodiment 1 can be at least 15 MPa.

15. The pressurized polymer bead of embodiment 1 can have a density of less than 1.1 g/cc.

16. The pressurized polymer bead of embodiment 1 can be mixed into a fracturing fluid.

17. The fracturing fluid of embodiment 16 can include an additive configured to reduce friction during pumping.

18. The additive of embodiment 17 can include a polymer, a long chain hydrocarbon, an ionic surfactant, a nonionic surfactant, a polyacrylamide, a polyethylene oxide (PEO), or any combinations thereof.

19. The fracturing fluid of embodiment 17 can be injected into a hydrocarbon reservoir.

20. Another embodiment provides a fracturing fluid that includes a carrier fluid and a number of pressurized beads mixed with the carrier fluid The pressurized beads include a substantially impermeable outer shell formed from a polyimide polymer and a core region that is at a pressure that is greater than 5 MPa.

21. The pressurized beads of embodiment 20 can be formed using pyromellitic dianhydride, 4,4′-oxydianiline, diisocyanates, diamines, dianhydrides, or any combinations thereof.

22. The carrier fluid of embodiment 20 can include brine, water, a hydrocarbon, or mixtures thereof.

23. The fracturing fluid of embodiment 20 can include an additive configured to reduce friction during pumping.

24. The additive of embodiment 23 can include a polymer, a long chain hydrocarbon, an ionic surfactant, a nonionic surfactant, a polyacrylamide, a polyethylene oxide (PEO), or any combinations thereof.

25. The average density of the pressurized beads of embodiment 20 can substantially match the density of the carrier fluid.

26. The fracturing fluid of embodiment 20 can include sand, shell fragments, ceramic spheres, or any combinations thereof.

27. Another embodiment provides a method for manufacturing a pressurized polymer bead. The method includes: forming a bubble comprising a monomer solution, wherein the monomer solution comprises an polyamic acid; dropping the bubble into a heated gas tube to form a dry hollow bead; dropping the hollow bead into a chemical bath to form a partially imidized bead; and heating the bead in the presence of a pressurized gas to form the pressurized bead.

28. The bubble of embodiment 27 can be formed by blowing a fluid through the monomer solution.

29. The bubble of embodiment 27 can be formed by coating a piece of polymer foam with the monomer solution.

30. In the method of embodiment 27, a sealing layer can be formed over the pressurized bead.

31. In the method of embodiment 27, a protective coating can be formed over the pressurized bead.

32. In the method of embodiment 27, a metal film can be formed over the pressurized bead by vapor deposition.

33. Another method described herein provides a method for harvesting hydrocarbons from a reservoir. The method includes: injecting a fracturing fluid into a reservoir to create fractures in rock in the reservoir. The fracturing fluid includes: a carrier fluid; and a number of pressurized beads mixed with the carrier fluid. The pressurized beads include a substantially impermeable outer shell formed from a polyimide polymer and a core region at a pressure that is at least 5 Mpa. The carrier fluid is withdrawn from the reservoir, leaving at least a portion of the pressurized beads in the fractures. A hydrocarbon is produced from the reservoir through the fractures.

34. The density of the pressurized beads of embodiment 33 can be substantially matched to the density of the carrier fluid.

35. A friction reducing additive can be added to the fracturing fluid of embodiment 33.

36. The polyimide polymer of embodiment 33 can be formed using pyromellitic dianhydride, 4,4′-oxydianiline, diisocyanates, diamines, dianhydrides, or any combinations thereof.

37. The produced hydrocarbon of embodiment 33 can include a gas, a liquid, or any combinations thereof.

38. The pressurized beads of embodiment 33 can be formed with a foam core.

What is claimed is:

1. A pressurized polymer bead for use as a proppant in hydraulic fracturing, comprising:
a shell comprising a polyimide polymer; and
a core region within the shell that is at a pressure of not less than 5 MPa.

2. The pressurized polymer bead of claim 1, wherein the polyimide polymer is formed using pyromellitic dianhydride, 4,4′-oxydianiline, diisocyanates, diamines, dianhydrides, or any combinations thereof.

3. The pressurized polymer bead of claim 1, wherein the core region comprises gas, liquid, foam, or combinations thereof.

4. The pressurized polymer bead of claim 1, wherein the core region comprises a gas and a damage removal fluid.

5. The pressurized polymer bead of claim 4, wherein the damage removal fluid comprises an oxidizer, an acid, an enzyme, or any combinations thereof.

6. The pressurized polymer bead of claim 1, wherein the core region comprises a foamed polymer.

7. The pressurized polymer bead of claim 1, wherein the shell comprises an outer layer and an inner layer, and at least one of the outer layer and inner layer comprise a polyimide polymer.

8. The pressurized polymer bead of claim 7, wherein the outer layer comprises at least one of a metal film, a polymer, or both.

9. The pressurized polymer bead of claim 8, wherein the polymer comprises a polyolefin, a poly (ether ether ketone) (PEEK), a styrenic polymer, a poly(phenylene sulfide), an elastomeric polymer, or multiple layers thereof.

10. The pressurized polymer bead of claim 7, wherein the inner layer comprises a polyimide layer.

11. The pressurized polymer bead of claim 1, comprising an inner layer disposed on the inside surface of the shell and an outer layer disposed on the outer surface of the shell.

12. The pressurized polymer bead of claim 1, comprising a thickness for the shell configured to substantially match the density of the pressurized bead to a carrier fluid.

13. The pressurized polymer bead of claim 1, wherein the pressurized bead is between 0.5 millimeter in diameter and 1 millimeter in diameter.

14. The pressurized polymer bead of claim 1, wherein the pressure is not less than 15 MPa.

15. The pressurized polymer bead of claim 1, wherein the pressurized polymer bead has a density of less than 1.1 g/cc.

16. The pressurized polymer bead of claim 1, wherein the pressurized polymer bead is mixed into a fracturing fluid.

17. The pressurized polymer bead of claim 16, wherein the fracturing fluid comprises an additive configured to reduce friction during pumping.

18. The pressurized polymer bead of claim 17, wherein the additive comprises a polymer, a long chain hydrocarbon, an ionic surfactant, a nonionic surfactant, a polyacrylamide, a polyethylene oxide (PEO), or any combinations thereof.

19. The pressurized polymer bead of claim 16, wherein the fracturing fluid is injected into a hydrocarbon reservoir.

20. A fracturing fluid, comprising:
a carrier fluid; and
a plurality of pressurized beads mixed with the carrier fluid, wherein the pressurized beads comprise:
a shell comprising a polyimide polymer; and
a core region within the shell that is at a pressure of not less than 5 MPa.

21. The fracturing fluid of claim 20, wherein the plurality of pressurized beads are formed using at least one of pyromellitic dianhydride, 4,4′-oxydianiline, diisocyanates, diamines, dianhydrides, and combinations thereof.

22. The fracturing fluid of claim 20, wherein the carrier fluid comprises brine, water, a hydrocarbon, or mixtures thereof.

23. The fracturing fluid of claim 20, comprising an additive configured to reduce friction during pumping.

24. The fracturing fluid of claim 23, wherein the additive comprises a polymer, a long chain hydrocarbon, an ionic surfactant, a nonionic surfactant, a polyacrylamide, a polyethylene oxide (PEO), or any combinations thereof.

25. The fracturing fluid of claim 20, wherein an average density of the plurality of pressurized beads substantially matches the density of the carrier fluid.

26. The fracturing fluid of claim 20, comprising sand, shell fragments, ceramic spheres, or any combinations thereof.

27. A method for manufacturing a pressurized polymer bead, comprising:
forming a bubble comprising a monomer solution, wherein the monomer solution comprises an polyamic acid;
dropping the bubble into a heated gas tube to form a dry hollow bead;
dropping the hollow bead into a chemical bath to form a partially imidized bead; and
heating the bead in the presence of a pressurized gas to form the pressurized bead.

28. The method of claim 27, wherein the bubble is formed by blowing a fluid through the monomer solution.

29. The method of claim 27, wherein the bubble is formed by coating a piece of polymer foam with the monomer solution.

30. The method of claim 27, comprising forming a sealing layer over the pressurized bead.

31. The method of claim 27, comprising forming a protective coating over the pressurized bead.

32. The method of claim 27, comprising forming a metal film over the pressurized bead by vapor deposition.

33. A method for harvesting hydrocarbons from a reservoir, comprising:
injecting a fracturing fluid into a reservoir to create fractures in rock in the reservoir, wherein the fracturing fluid comprises:
a carrier fluid; and
a plurality of pressurized beads mixed with the carrier fluid, wherein the pressurized beads comprise:
a substantially impermeable outer shell formed from a polyimide polymer; and
a core region that is at a pressure that is not less than 5 M Pa; and
withdrawing the carrier fluid from the reservoir, wherein at least a portion of the plurality of pressurized beads remain in the fractures; and
producing a hydrocarbon from the reservoir through the fractures.

34. The method of claim 33, comprising substantially matching the density of the plurality of pressurized beads to the density of the carrier fluid.

35. The method of claim 33, comprising adding a friction reducing additive to the fracturing fluid.

36. The method of claim 33, comprising forming the polyimide polymer using pyromellitic dianhydride, 4,4′-oxydianiline, diisocyanates, diamines, dianhydrides, or any combinations thereof.

37. The method of claim 33, wherein the produced hydrocarbon comprises a gas, a liquid, or any combinations thereof.

38. The method of claim 33, comprising forming the pressurized beads with a foam core.
